(19) United States
(12) Patent Application Publication
(10) Pub. No.: US 2026/0371866 A1
(43) Pub. Date: Nov. 19, 2026

(54) DISPLAY DEVICE

(71) Applicant: Sharp Display Technology Corporation, Kameyama City, Mie (JP)

(72) Inventors: Tohru OKABE, Kameyama City, Mie (JP); Shoji OKAZAKI, Kameyama City, Mie (JP); Shinji ICHIKAWA, Kameyama City, Mie (JP); Hiroki TANIYAMA, Kameyama City, Mie (JP); Eiji FUJIMOTO, Kameyama City, Mie (JP)

(21) Appl. No.: 19/145,664

(22) PCT Filed: Jan. 5, 2023
(86) PCT No.: PCT/JP2023/000067

§ 371 Date: Jul. 3, 2025

(30) Foreign Application Priority Data
Jun. 20, 2023 (JP) 2023100678

(51) Int. Cl. H10K 59/131; G09G 3/3233; H04N 23/57

(52) U.S. Cl. CPC H10K 59/131; G09G 3/3233; G09G 2300/0426; G09G 2300/0842; H04N 23/57

(57) ABSTRACT

An organic EL display device (1) includes a TFT layer (20) and a light-emitting element layer (60) sequentially provided on a substrate layer (10). A camera (3) is disposed on a back face side of the substrate layer. In a display region, a second display region (DA2) inside a first display region (DA1) transmits external light received by the camera. In the second display region (DA2), connection lines (40r) configured to electrically connect TFTs (50) and organic EL elements (70) are provided. The connection lines include a transparent wiring line layer (TL1). Pixel electrodes in the second display region include a first region (PB1) provided overlapping the transparent wiring line layer and a second region (PB2) formed on the same layer as the transparent wiring line layer.

### TECHNICAL FIELD

The disclosure relates to a display device.

### BACKGROUND ART

In recent years, organic electro luminescence (hereinafter, referred to as EL) display devices using organic EL display devices are used in practical applications. In a case where the organic EL display device is used as a display of an information terminal such as a smartphone or a tablet terminal, or in a case where the organic EL display device is used as a display for performing bidirectional communication such as a video telephone call or a video conference, the organic EL display device is combined with a camera that captures an image on the front face side where the captured image is displayed, that is, combined with a so-called in-camera.

It is proposed for such an organic EL display device provided with an in-camera to dispose a camera at the position overlapping the display region on the back face side of the organic EL display device in a plan view. An example of the organic EL display device discussed above is disclosed in PTL 1.

### CITATION LIST

### Patent Literature

PTL 1: JP 2022-041886 A

### SUMMARY

### Technical Problem

In the above-described organic EL display device with an in-camera, the portion of the display region overlapping the camera in a plan view is regarded as a transmissive region that transmits external light. In the transmissive region, connection lines for connecting organic EL elements and pixel circuits are provided. It is preferable for both the connection lines to be configured by a transparent wiring line layer having optical transparency in order to raise transmittance with respect to light to be utilized by the camera in the display region. When the organic EL elements are of a top emission type, the pixel electrodes constituting the organic EL elements have light reflectivity. For this reason, the pixel electrodes and the transparent wiring line layer need to be formed separately. In such a case, the pixel electrodes are provided to overlap the transparent wiring line layer so as to be located inside the transparent wiring line layer in a plan view.

When such a configuration is adopted; however, as an alignment margin for each light-emitting element, a margin corresponding to the sum of the margin between both patterns of the transparent conductive layer and the pixel electrodes and the margin between both patterns of the pixel electrodes and constituent elements provided on the upper layer is needed. For this reason, it is necessary to ensure a relatively long distance between adjacent pixel electrodes. As a result, the configuration hinders high definition of display images on the display device. This problem also occurs when a transparent conductive layer is formed of the same material in the same layer as the transparent wiring line layer in a general portion in the display region outside the transmissive region and the pixel electrodes are provided so as to overlap the transparent conductive layer.

An object of the disclosure is to increase the transmittance with respect to light used by electronic components in a display region and to increase the definition of display images in a display device in which the electronic components using light are disposed to overlap the back face side of the display region.

### Solution to Problem

The disclosure relates to a display device. In a first aspect, the display device according to the disclosure includes a substrate, a thin film transistor layer provided on the substrate, and a light-emitting element layer provided on the thin film transistor layer. A plurality of thin film transistors are provided in the thin film transistor layer and a plurality of light-emitting elements are provided in the light-emitting element layer, the plurality of thin film transistors and the plurality of light-emitting elements being provided corresponding to each of a plurality of subpixels forming a display region. An electronic component that uses light is disposed on a back face side of the substrate at a position overlapping the display region in a plan view. The display region includes a first display region and a second display region that is provided inside the first display region and transmits light to be used by the electronic component. A connection line configured to electrically connect each of the plurality of thin film transistors and a corresponding one of the plurality of light-emitting elements is provided in the second display region. The connection line includes a transparent wiring line layer having optical transparency. A pixel electrode in the second display region includes a first region provided overlapping the transparent wiring line layer and a second region formed on the same layer as the transparent wiring line layer.

In addition, in a second aspect, the display device according to the disclosure includes a substrate, a thin film transistor layer provided on the substrate, and a light-emitting element layer provided on the thin film transistor layer. A plurality of thin film transistors are provided in the thin film transistor layer and a plurality of light-emitting elements are provided in the light-emitting element layer, each of the plurality of thin film transistors and the plurality of light-emitting elements being provided corresponding to each of a plurality of subpixels forming a display region. An electronic component that uses light is disposed on a back face side of the substrate at a position overlapping the display region in a plan view. The display region includes a first display region and a second display region that is provided inside the first display region and transmits light to be used by the electronic component. A connection line configured to electrically connect each of the plurality of thin film transistors and a corresponding one of the plurality of light-emitting elements is provided in the second display region. The connection line includes a transparent wiring line layer having optical transparency. A pixel electrode in the first display region includes a first region provided overlapping a transparent conductive layer formed of the same material and in the same layer as the transparent wiring line layer and a second region formed on the same layer as the transparent conductive layer.

### Advantageous Effects of Disclosure

With the display device according to the disclosure, transmittance with respect to light used by electronic components can be increased in a display region and high definition of displayed images can be achieved.

### BRIEF DESCRIPTION OF DRAWINGS

FIG. 1 is a plan view illustrating a schematic configuration of an organic EL display device according to a first embodiment.

FIG. 2 is a cross-sectional view of the organic EL display device taken along line II-II in FIG. 1.

FIG. 3 is a plan view illustrating pixels and various wiring lines in a first display region of the organic EL display device.

FIG. 4 is a cross-sectional view of the first display region of the organic EL display device taken along line IV-IV in FIG. 3.

FIG. 5 is an equivalent circuit diagram illustrating a pixel circuit.

FIG. 6 is a plan view illustrating a schematic configuration of a second display region and its vicinity of the organic EL display device.

FIG. 7 is a plan view illustrating a main portion of the organic EL display device surrounded by line VII in FIG. 6.

FIG. 8 is a cross-sectional view of the main portion of the organic EL display device taken along line VIII-VIII in FIG. 7.

FIG. 9 is a cross-sectional view of the main portion of the organic EL display device taken along line IX-IX in FIG. 7.

FIG. 10 is a cross-sectional view illustrating a part of a manufacturing step of the organic EL display device according to the first embodiment. The drawing on the right side of FIG. 10 is a cross-sectional view of the portion corresponding to FIG. 4, and the drawing on the left side of FIG. 10 is a cross-sectional view of the portion corresponding to FIG. 8.

FIG. 11 is a cross-sectional view illustrating a part of the manufacturing step of the organic EL display device according to the first embodiment. The drawing on the right side of FIG. 11 is a cross-sectional view of the portion corresponding to FIG. 4, and the drawing on the left side of FIG. 11 is a cross-sectional view of the portion corresponding to FIG. 8.

FIG. 12 is a cross-sectional view illustrating a part of the manufacturing step of the organic EL display device according to the first embodiment. The drawing on the right side of FIG. 12 is a cross-sectional view of the portion corresponding to FIG. 4, and the drawing on the left side of FIG. 12 is a cross-sectional view of the portion corresponding to FIG. 8.

FIG. 13 is a cross-sectional view illustrating a part of the manufacturing step of the organic EL display device according to the first embodiment. The drawing on the right side of FIG. 13 is a cross-sectional view of the portion corresponding to FIG. 4, and the drawing on the left side of FIG. 13 is a cross-sectional view of the portion corresponding to FIG. 8.

FIG. 14 is a cross-sectional view illustrating a part of the manufacturing step of the organic EL display device according to the first embodiment. The drawing on the right side of FIG. 14 is a cross-sectional view of the portion corresponding to FIG. 4, and the drawing on the left side of FIG. 14 is a cross-sectional view of the portion corresponding to FIG. 8.

FIG. 15 is a cross-sectional view illustrating a part of the manufacturing step of the organic EL display device according to the first embodiment. The drawing on the right side of FIG. 15 is a cross-sectional view of the portion corresponding to FIG. 4, and the drawing on the left side of FIG. 15 is a cross-sectional view of the portion corresponding to FIG. 8.

FIG. 16 is a cross-sectional view illustrating a part of the manufacturing step of the organic EL display device according to the first embodiment. The drawing on the right side of FIG. 16 is a cross-sectional view of the portion corresponding to FIG. 4, and the drawing on the left side of FIG. 16 is a cross-sectional view of the portion corresponding to FIG. 8.

FIG. 17 is a cross-sectional view illustrating a part of the manufacturing step of the organic EL display device according to the first embodiment. The drawing on the right side of FIG. 17 is a cross-sectional view of the portion corresponding to FIG. 4, and the drawing on the left side of FIG. 17 is a cross-sectional view of the portion corresponding to FIG. 8.

FIG. 18 is a cross-sectional view illustrating a part of the manufacturing step of the organic EL display device according to the first embodiment. The drawing on the right side of FIG. 18 is a cross-sectional view of the portion corresponding to FIG. 4, and the drawing on the left side of FIG. 18 is a cross-sectional view of the portion corresponding to FIG. 8.

FIG. 19 is a cross-sectional view illustrating a part of the manufacturing step of the organic EL display device according to the first embodiment. The drawing on the right side of FIG. 19 is a cross-sectional view of the portion corresponding to FIG. 4, and the drawing on the left side of FIG. 19 is a cross-sectional view of the portion corresponding to FIG. 8.

FIG. 20 is a cross-sectional view illustrating a part of a manufacturing step of the organic EL display device according to the first embodiment. The drawing on the right side of FIG. 20 is a cross-sectional view of the portion corresponding to FIG. 4, and the drawing on the left side of FIG. 20 is a cross-sectional view of the portion corresponding to FIG. 8.

FIG. 21 is a cross-sectional view of a first display region of an organic EL display device according to a second embodiment corresponding to FIG. 4.

FIG. 22 is a cross-sectional view illustrating a part of a manufacturing step of the organic EL display device according to the second embodiment. The drawing on the right side of FIG. 22 is a cross-sectional view of the portion corresponding to FIG. 4, and the drawing on the left side of FIG. 22 is a cross-sectional view of the portion corresponding to FIG. 8.

FIG. 23 is a cross-sectional view illustrating a part of the manufacturing step of the organic EL display device according to the second embodiment. The drawing on the right side of FIG. 23 is a cross-sectional view of the portion corresponding to FIG. 4, and the drawing on the left side of FIG. 23 is a cross-sectional view of the portion corresponding to FIG. 8.

FIG. 24 is a cross-sectional view of a first display region of an organic EL display device according to a third embodiment corresponding to FIG. 4.

FIG. 25 is a cross-sectional view illustrating a part of a manufacturing step of the organic EL display device according to the third embodiment. The drawing on the right side of FIG. 25 is a cross-sectional view of the portion corresponding to FIG. 4, and the drawing on the left side of FIG. 25 is a cross-sectional view of the portion corresponding to FIG. 8.

FIG. 26 is a cross-sectional view illustrating a part of the manufacturing step of the organic EL display device according to the third embodiment. The drawing on the right side of FIG. 26 is a cross-sectional view of the portion corresponding to FIG. 4, and the drawing on the left side of FIG. 26 is a cross-sectional view of the portion corresponding to FIG. 8.

### DESCRIPTION OF EMBODIMENTS

Exemplary embodiments will be described below in detail with reference to the drawings. In the embodiments described below, an organic EL display device is described as an example of a display device according to the disclosure. Note that the drawings are for schematically describing the techniques of the disclosure. Thus, in the drawings, the dimensions, ratios, or numbers may be exaggerated or simplified to facilitate the techniques of the disclosure.

In the following embodiments, “first direction” indicates the horizontal direction of the screen of a display device in a predetermined use state. “Second direction” is a direction orthogonal to the first direction and indicates the vertical direction of the screen of the display device in a predetermined use state. A row of constituent elements such as subpixels indicates a horizontal arrangement of a plurality of constituent elements forming a line in the first direction. A column of constituent elements such as subpixels indicates a vertical arrangement of a plurality of constituent elements forming a line in the second direction.

In the following embodiments, the description that a constituent element such as a certain film, layer, or element is provided or formed on a constituent element such as another film, layer, or element means not only a case in which the other constituent element is present immediately above the certain constituent element but also a case in which constituent elements on both sides sandwich the remaining constituent elements such as films, layers, or elements therebetween.

In addition, in the following embodiments, the description that a certain constituent element is connected to another constituent element indicates that the constituent elements are electrically connected unless otherwise specified. This description indicates not only direct connection of the constituent elements but also indirect connection thereof via other constituent elements, without departing from the gist of the technique of the disclosure. The description further includes a case in which a certain constituent element is integrated with another constituent element, that is, a part of the certain constituent element constitutes the other constituent element.

In addition, in the following embodiments, a description that a certain constituent element and another constituent element are in the same layer means that the certain constituent element and the other constituent element are formed through the same process. A description that a certain constituent element is in a lower layer below another constituent element signifies that the certain constituent element is formed through a process performed earlier than that of the other constituent element. A description that a certain constituent element is an upper layer above another constituent element signifies that the certain constituent element is formed through a process performed later than that of the other constituent element.

In addition, in the following embodiments, the description that a certain constituent element is the same as or equivalent to another constituent element includes not only a state in which the certain constituent element is completely the same as or completely equivalent to the other constituent element, but also a state in which the certain constituent element is substantially the same as or substantially equivalent to the other constituent element, such as a state in which the certain constituent element and the other constituent element vary within a range of a manufacturing variation, tolerance, or the like.

In addition, in the following embodiments, the designations ‘first’, ‘second’, ‘third’, and so forth are used to differentiate the associated words and phrases, and there is no intent to impose any limitations on the number or order of these words and phrases.

### First Embodiment

An organic EL display device 1 of the present embodiment is used for mobile apparatuses such as a multifunctional telephone called a smartphone and a tablet terminal. The organic EL display device 1 may be used in various other apparatuses such as personal computers (PCs) and television devices.

### Configuration of Organic El Display Device

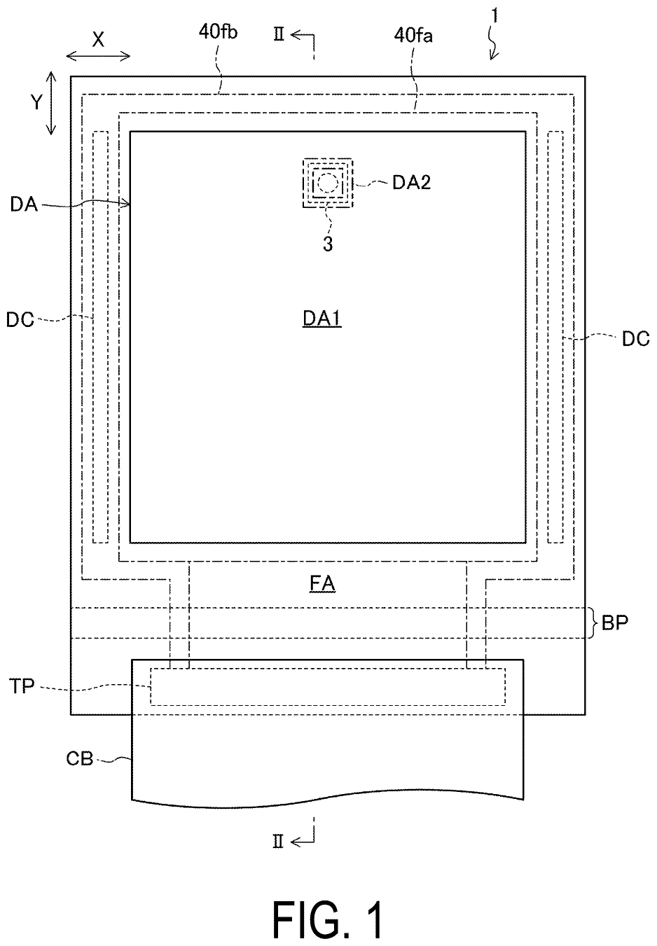

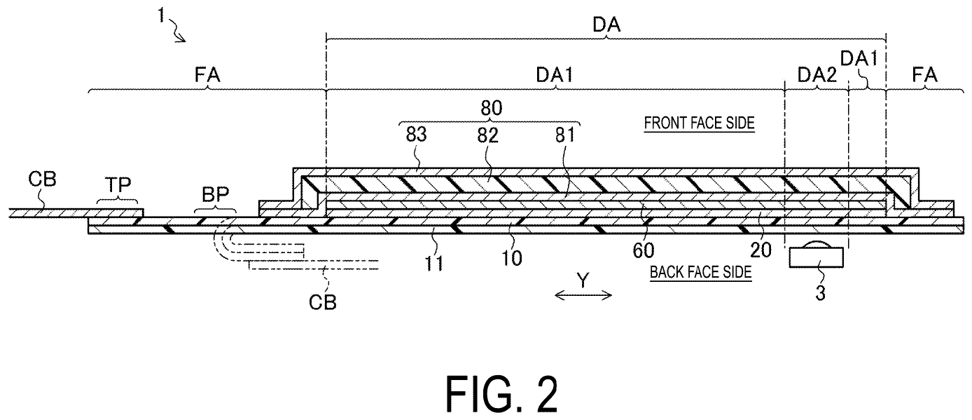

The organic EL display device 1 constitutes a display device with an in-camera 3, which is combined with a camera 3 that captures an image of the side in front of a screen as illustrated in FIGS. 1 and 2. The organic EL display device 1 includes a display region DA and a frame region FA.

The display region DA is a region in which an image is displayed. The display region DA constitutes a screen. The display region DA is provided in a rectangular shape, for example. The display region DA may have a substantially rectangular shape such as a shape in which at least one side is arc-shaped, a shape in which at least one corner is arc-shaped or a shape in which a cutout portion is formed in at least one side, or may have any other shape.

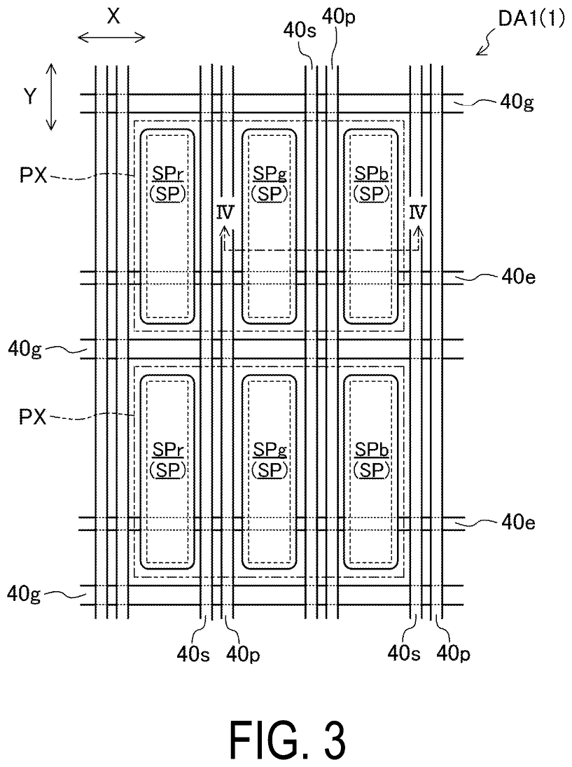

As illustrated in FIG. 3, the display region DA includes a plurality of pixels PX. The plurality of pixels PX are arrayed in a matrix shape. Each pixel PX is constituted by three subpixels SP. The three subpixels SP are a subpixel SPr for emitting red light, a subpixel SPg for emitting green light, and a subpixel SPb for emitting blue light. These three subpixels SPr, SPg, and SPb are arrayed in a stripe shape, for example.

As illustrated in FIGS. 1 and 2, the camera 3 is disposed at a position overlapping the display region DA in a plan view on the back face side of a substrate layer 10 constituting the organic EL display device 1. The camera 3 is an example of an electronic component using light. The camera 3 includes an image sensor, for example, which is a charge coupled device (CCD) or a complementary metal oxide semiconductor (CMOS). The camera 3 is installed inside a housing (not illustrated) that houses the organic EL display device 1.

The display region DA includes a first display region DA1 and a second display region DA2. The first display region DA1 is a region that occupies most of the display region DA. The second display region DA2 is provided within the first display region DA1. The second display region DA2 is a region including a portion that transmits light to be used by the camera 3. The second display region DA2 is provided in a rectangular shape at one side (upper side in FIG. 1) of the display region DA, for example. The second display region DA2 may have another shape such as a circular shape or an elliptical shape.

The frame region FA is a region constituting a non-display region other than the screen. The frame region FA is provided in a rectangular frame shape, for example. The frame region FA may have a frame shape other than a rectangular shape. The frame region FA includes a terminal portion TP and a bending portion BP. The terminal portion TP is a portion for connecting to an external circuit (such as a display control circuit). The terminal portion TP is provided at a position close to an outer edge of a portion constituting one side of the frame region FA such that the terminal portion extends in a first direction X along the one side.

The bending portion BP is provided between the terminal portion TP in the frame region FA and the display region DA. The bending portion BP is a portion to be bent about a bending axis extending in the first direction X. The bending portion BP extends horizontally across the entire frame region FA in the first direction X. Although not illustrated, in the bending portion BP, an inorganic insulating film constituting a TFT layer 20 is removed to obtain higher flexibility than in other portions.

The frame region FA of the organic EL display device 1 is bent by, for example, about 180° so as to form a U shape at the bending portion BP (indicated by a two-dot chain line in FIG. 2).

Thus, the terminal portion TP is disposed on the back face side of the organic EL display device 1. The terminal portion TP includes a plurality of terminals although not illustrated. A wiring line substrate CB such as a flexible printed circuit (FPC) is connected to the terminal portion TP.

Drive circuits DC are provided in the frame region FA of the organic EL display device 1. In the frame region FA, the drive circuits DC are each disposed in a portion constituting a side (each of the left or right side in FIG. 1) adjacent to the side on which the terminal portion TP is provided. The drive circuits DC are monolithically formed as a part of the TFT layer 20 to be described below. The drive circuits DC include a gate driver and an emission driver.

In the frame region FA of the organic EL display device 1, a first frame line 40fa and a second frame line 40fb are provided. The first frame line 40fa and the second frame line 40fb are each formed to surround the display region DA and extend to the terminal portion TP. A high-level power supply voltage (ELVDD) is supplied to the first frame line 40fa via the wiring line substrate CB. A low-level power supply voltage (ELVSS) is supplied to the second frame line 40fb via the wiring line substrate CB.

The organic EL display device 1 employs an active matrix driving method. In the organic EL display device 1, light emission from each of the subpixels SP is controlled by a thin film transistor (hereinafter referred to as a “TFT”) 50, so that image display is performed by operations of the TFT 50. The organic EL display device 1 includes the substrate layer 10, the TFT layer (thin film transistor layer) 20, a light-emitting element layer 60, and a sealing film 80 as illustrated in FIG. 2.

### Substrate Layer

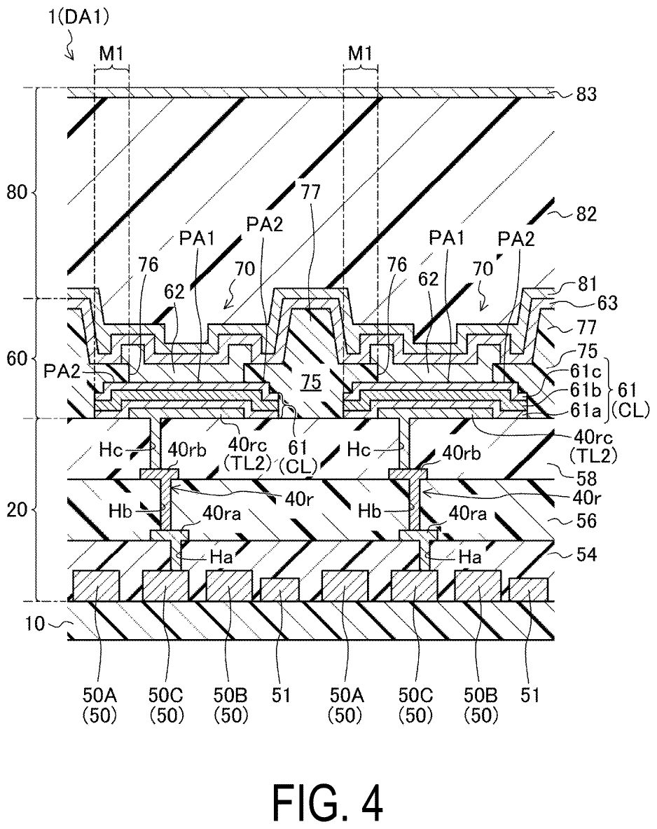

The substrate layer 10 is a layer forming a base of the organic EL display device 1. The substrate layer 10 is an example of a substrate. The substrate layer 10 has both optical transparency (which refers to transparency of visible light in the present example; the same applies hereinafter) and flexibility. The substrate layer 10 is formed of an organic resin material such as a polyimide resin, a polyamide resin, or an epoxy resin. A protection film 11 having optical transparency (not illustrated in FIGS. 4, 8, 9, 21, and 24 to be referred to hereinafter) is bonded to the back face of the substrate layer 10.

### TFT Layer

The TFT layer 20 is provided on the substrate layer 10. The TFT layer 20 includes the above-described drive circuits DC. The TFT layer 20 further includes various wiring lines 40.

The various wiring lines 40 include the first frame line 40fa and the second frame line 40fb described above. As the various wiring lines 40, a plurality of gate lines 40g, a plurality of light emission control lines 40e, a plurality of power source lines 40p, and a plurality of source lines 40s illustrated in FIG. 3 are provided. The gate lines 40g and the light emission control lines 40e are examples of first metal lines. The source lines 40s and the power source lines 40p are examples of second metal lines.

Each of the plurality of gate lines 40g is a wiring line that transmits a gate signal. The plurality of gate lines 40g are disposed at intervals between each other in a second direction Y in the display region DA, and extend in parallel to each other in the first direction X. The gate lines 40g are provided for each row of the subpixels SP. Each of the gate lines 40g is connected to the gate driver of the drive circuit DC.

Each of the plurality of light emission control lines 40e is a wiring line that transmits an emission signal. The plurality of light emission control lines 40e are disposed at intervals between each other in the second direction Y in the display region DA, and extend in parallel to each other in the first direction X. The light emission control lines 40e are provided for each row of the subpixels SP. Each of the light emission control lines 40e is connected to the emission driver of the drive circuit DC.

Each of the plurality of power source lines 40p is a wiring line that applies a predetermined high-level power supply voltage (ELVDD). The plurality of power source lines 40p are disposed at intervals between each other in the first direction X in the display region DA, and extend in parallel to each other in the second direction Y. The power source lines 40p are provided for each column of the subpixels SP. Each power source line 40p is connected to the first frame line 40fa.

Each of the plurality of source lines 40s is a wiring line that transmits a source signal. The plurality of source lines 40s are disposed at intervals between each other in the first direction X in the display region DA, and extend in parallel to each other in the second direction Y. The source lines 40 s are provided for each column of the subpixels SP. Each source line 40s is extended to the terminal portion TP and connected to the display control circuit (source driver) via the wiring line substrate CB.

The TFT layer 20 further includes a plurality of TFTs 50, a plurality of capacitors 51, a first flattening film 54, a second flattening film 56, a third flattening film 58, and a plurality of connection lines 40r as illustrated in FIGS. 4, 8, and 9.

The plurality of TFTs 50 are provided corresponding to a plurality of subpixels SP. A plurality of TFTs 50 are provided for each subpixel SP. In the present example, the plurality of TFTs 50 provided for each subpixel SP are a first TFT 50A, a second TFT 50B, and a third TFT 50C. All of the first TFT 50A, the second TFT 50B, and the third TFT 50C are configured as, for example, the top gate type. Although not illustrated, each of the first TFT 50A, the second TFT 50B, and the third TFT 50C includes a gate electrode, a first terminal electrode, and a second terminal electrode.

At least one capacitor 51 is provided for each of the subpixels SP. Although not illustrated, the capacitor 51 includes a first capacitance electrode and a second capacitance electrode. The first capacitance electrode and the second capacitance electrode overlap each other via an insulating film (not illustrated) included in the TFT layer 20. Each of the first capacitance electrode and the second capacitance electrode may be configured by another electrode or a part of a wiring line.

The first flattening film 54 is provided to cover the plurality of TFTs 50 and the plurality of capacitors 51. The second flattening film 56 and the third flattening film 58 are layered on the first flattening film 54 in this order. The first flattening film 54, the second flattening film 56, and the third flattening film 58 expand across the entire display region DA. The surface of the TFT layer 20 is flattened by the first flattening film 54, the second flattening film 56, and the third flattening film 58.

The connection lines 40r are wiring lines connecting a predetermined TFT 50 (third TFT 50C) and an organic EL element 70, and a plurality of connection lines are provided in each of the first display region DA1 and the second display region DA2. The connection lines 40r in the first display region DA1 are provided for each of the subpixels SP. The connection lines 40r in the second display region DA2 are provided for each of pixel circuits PC.

Each of the plurality of connection lines 40 r includes a lower layer connection line 40ra, an intermediate connection line 40rb, and an upper layer connection line 40rc. The lower layer connection line 40ra, the intermediate connection line 40rb, and the upper layer connection line 40rc are formed in layers different from each other. The intermediate connection line 40rb corresponds to a second connection line. The upper layer connection line 40rc corresponds to a first connection line.

Each lower layer connection line 40ra is provided on the first flattening film 54. The lower layer connection line 40ra is a wiring line connecting a predetermined TFT 50 (the third TFT 50C) and the intermediate connection line 40rb, and is located below the second flattening film 56. The lower layer connection line 40ra is formed in an island shape for each subpixel SP in the first display region DA1 and for each pixel circuit PC in the second display region DA2. Each lower layer connection line 40ra is connected to the predetermined TFT 50 (the third TFT 50C) via a first contact hole Ha formed in the first flattening film 54.

Each intermediate connection line 40rb is provided on the second flattening film 56. The intermediate connection line 40rb is a wiring line connecting the lower layer connection line 40ra, the upper layer connection line 40rc, and the predetermined TFT 50 (the third TFT 50C), and is located below the third flattening film 58. The intermediate connection line 40rb is formed in an island shape for each subpixel SP in the first display region DA1 and for each pixel circuit PC in the second display region DA2. Each intermediate connection line 40rb is connected to the corresponding lower layer connection line 40ra via a second contact hole Hb formed in the second flattening film 56.

Each upper layer connection line 40rc is provided on the third flattening film 58. The upper layer connection line 40rc is a wiring line connecting the intermediate connection line 40rb and the organic EL element 70, and is located below the pixel electrodes 61 constituting the organic EL element 70. The upper layer connection line 40rc is formed in an island shape for each subpixel SP in the first display region DA1 and for each pixel circuit PC in the second display region DA2.

Each upper layer connection line 40rc is connected to the pixel electrode 61 and connected to the corresponding intermediate connection line 40rb through a third contact hole Hc formed in the third flattening film 58.

The above-mentioned various wiring lines and electrodes are each made of a metal material, for example, aluminum (Al), tungsten (W), molybdenum (Mo), tantalum (Ta), chromium (Cr), titanium (Ti), or copper (Cu), and configured by a single-layer film or a layered film, excluding the intermediate connection line 40rb and the upper layer connection line 40rc. Each of the intermediate connection line 40rb and the upper layer connection line 40rc (transparent wiring line layer TL1 and the transparent conductive layer TL2) is formed of a crystallized transparent conductive material and is configured by a single-layer film or a layered film.

The transparent conductive material forming the intermediate connection line 40rb and the upper layer connection line 40rc (the transparent wiring line layer TL1 and the transparent conductive layer TL2) of the present example is indium tin oxide (ITO). The intermediate connection line 40rb and the upper layer connection line 40rc (the transparent wiring line layer TL1 and the transparent conductive layer TL2) have optical transparency, and have a low degree of absorption of wavelengths in the visible light spectrum. The lower layer connection line 40ra is preferably made of a metal material (for example, a metal material containing titanium (Ti)) having resistance to an etching solution used for patterning the intermediate connection line 40rb, that is, a metal material that is not corroded or is less corroded by the etching solution.

Each of the first flattening film 54, the second flattening film 56, and the third flattening film 58 is made of, for example, an organic resin material such as a polyimide resin or an acrylic resin, or a polysiloxane-based spin on glass (SOG) material. At least two flattening films among the first flattening film 54, the second flattening film 56, and the third flattening film 58 may be made of the same material. The first flattening film 54, the second flattening film 56, and the third flattening film 58 may be made of materials different from each other.

### Light-emitting Element Layer

The light-emitting element layer 60 is provided on the TFT layer 20. The light-emitting element layer 60 includes a plurality of the organic electroluminescence elements (organic EL elements) 70 and an edge cover 75, as illustrated in FIG. 4. The organic EL elements 70 are examples of light-emitting elements. The organic EL elements 70 are configured as a top-emitting type. In the organic EL elements 70, light emitted in an organic EL layer 62 is extracted from the sealing film 80 side.

The plurality of organic EL elements 70 are provided corresponding to a plurality of subpixels SP. The individual organic EL elements 70 constitute the subpixels SP. In addition, the plurality of organic EL elements 70 constitute the display region DA as a whole. Light emission of each of the organic EL elements 70 is controlled by operations of the plurality of TFTs 50 and the capacitors 51. Each of the organic EL elements 70 includes the pixel electrode 61, an organic EL layer 62, and a common electrode 63.

The pixel electrodes 61 are provided on the third flattening film 58 for each of the subpixel SP. The pixel electrodes 61 are arrayed in a matrix shape corresponding to the subpixels SP. The pixel electrodes 61 are connected to a predetermined TFT 50 via the lower layer connection line 40ra, the intermediate connection line 40rb, and the upper layer connection line 40rc. The pixel electrode 61 functions as an anode electrode, and injects holes into the organic EL layer 62.

The pixel electrodes 61 of the present example is configured by a conductive layered body CL. The conductive layered body CL is formed by layering a first transparent electrode layer 61a, a reflective electrode layer 61b, and a second transparent electrode layer 61c in this order. The first transparent electrode layer 61a, the reflective electrode layer 61b, and the second transparent electrode layer 61c are all formed of a conductive material having a property of being etched by a common etching solution (for example, a PAN-based etching solution).

The first transparent electrode layer 61a and the second transparent electrode layer 61c each have optical transparency. The first transparent electrode layer 61a and the second transparent electrode layer 61c of the present example are made of indium tin oxide (ITO). The first transparent electrode layer 61a and the second transparent electrode layer 61c may be formed of another transparent conductive material such as indium zinc oxide (IZO) or indium gallium zinc oxide (In—Ga—Zn—O). The reflective electrode layer 61b has light reflectivity. The reflective electrode layer 61b of the present example is made of silver (Ag). The reflective electrode layer 61b may be formed of other light-reflective metal materials such as silver alloys, aluminum (Al), and aluminum alloys.

The edge cover 75 is provided on the third flattening film 58. The edge cover 75 is formed in a lattice pattern to compartmentalize a plurality of the pixel electrodes 61. The edge cover 75 is positioned above the pixel electrodes 61 and covers the outer edge (peripheral end portion) of each pixel electrode 61. The edge cover 75 has a plurality of openings 76 that partially expose the pixel electrodes 61. The peripheral edge of each opening 76 of the edge cover 75 is surrounded by the outer edge of the pixel electrode 61 corresponding to the opening 76 in a plan view. An alignment margin M1 is provided between the peripheral edge of each opening 76 of the edge cover 75 and the outer edge of the pixel electrode 61 corresponding to the opening 76.

A part of the surface of the edge cover 75 constitutes a plurality of photo spacers 77 protruding to the sealing film 80 side. The photo spacers 77 are columnar spacers playing a role of maintaining an interval between a film-forming mask and the surface of a film-forming target to be used for forming a function layer (for example, the light-emitting layer) constituting the organic EL layer 62 in, for example, manufacturing of the organic EL display device 1. A plurality of photo spacers 77 are provided in a predetermined arrangement in each of the first display region DA1 and the second display region DA2, and a plurality of photo spacers 77 are also provided in the frame region FA.

The peripheral edge of each opening 76 of the edge cover 75 is surrounded by the outer edge of the corresponding pixel electrode 61 in a plan view. In addition, the peripheral edge of each opening 76 in the edge cover 75 may be positioned on the inner side of the corresponding transparent conductive layer TL2 or may be positioned on the outer side of the corresponding transparent conductive layer TL2 in a plan view. The edge cover 75 is made of, for example, an organic resin material such as a polyimide resin or an acrylic resin, or a polysiloxane-based SOG material.

The organic EL layer 62 is provided on the individual pixel electrode 61 in an opening 76 of the edge cover 75. The organic EL layer 62 includes a hole injection layer, a hole transport layer, a light-emitting layer, an electron transport layer, and an electron injection layer. The hole injection layer, the hole transport layer, the light-emitting layer, the electron transport layer, and the electron injection layer are layered in this order on the pixel electrode 61, and are made of known compounds suitable for the respective functions. The organic EL layer 62 emits light when a current is applied between the pixel electrode 61 and the common electrode 63.

The common electrode 63 is continuously provided to be common to the plurality of subpixels SP over the entire display region DA. The common electrode 63 covers the edge cover 75 and each organic EL layer 62, and overlaps each pixel electrode 61 via the organic EL layer 62. The common electrode 63 extends to the frame region FA and is connected to the second frame line 40fb. The common electrode 63 functions as a cathode electrode, and injects electrons into the organic EL layer 62. A conductive material having a small work function is preferably used for the common electrode 63.

Examples of the material of the common electrode 63 include an electrically conductive oxide such as indium tin oxide (ITO) or indium zinc oxide (IZO). The material of the common electrode 63 may be a metal such as silver (Ag), aluminum (Al), lithium (Li), magnesium (Mg), calcium (Ca), or ytterbium (Yb). The material of the common electrode 63 may be a metal compound or an alloy. The common electrode 63 may be formed by layering a plurality of layers including a conductive material.

### Sealing Film

The sealing film 80 is provided on the light-emitting element layer 60. As illustrated in FIG. 4, the sealing film 80 covers the plurality of organic EL elements 70 and protects each of the organic EL elements 70 (particularly, the organic EL layer 62) from moisture, oxygen, and the like. The sealing film 80 is provided over the entire display region DA and extends to the frame region FA. The sealing film 80 has, for example, a thin film encapsulation (TFE) structure. The sealing film 80 includes a first inorganic film 81, an organic film 82, and a second inorganic film 83. The first inorganic film 81, the organic film 82, and the second inorganic film 83 are provided in this order on the light-emitting element layer 60.

The first inorganic film 81 and the second inorganic film 83 extend closer to the outer peripheral side of the frame region FA than the organic film 82, and overlap each other in the peripheral edge portion of the frame region FA. The organic film 82 is enclosed by the first inorganic film 81 and the second inorganic film 83. The first inorganic film 81 and the second inorganic film 83 each include, for example, an inorganic insulating material such as silicon oxide, silicon nitride, or silicon oxynitride. The organic film 82 includes, for example, an organic resin material such as an acrylic resin, an epoxy resin, a silicone resin, a polyurea resin, a parylene resin, a polyimide resin, or a polyamide resin.

### Pixel Circuit

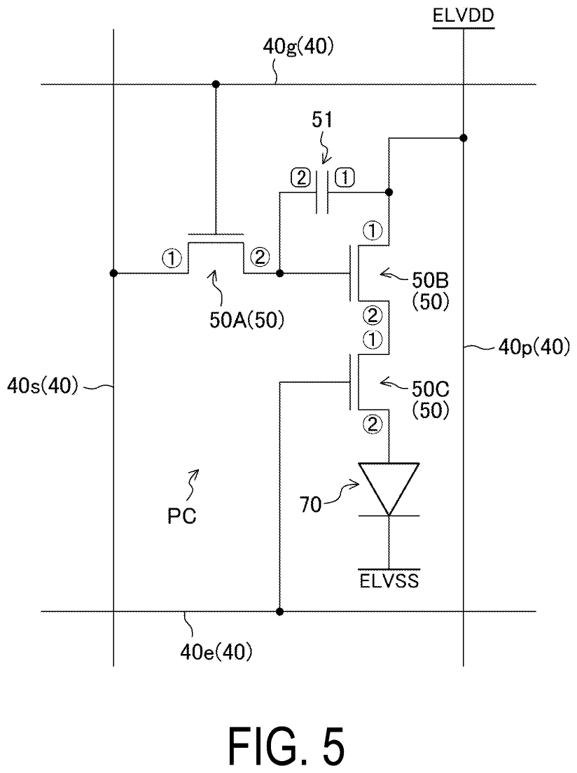

The plurality of TFTs 50 and capacitors 51 provided for each subpixel SP constitute the pixel circuit PC as illustrated in FIG. 5. The pixel circuit PC controls light emission of the organic EL element 70 based on a gate signal, an emission signal, a source signal, a high-level power supply voltage, and a low-level power supply voltage that are supplied through various wiring lines.

In the equivalent circuit diagram illustrated FIG. 5, the first terminal electrode of the TFT 50 is denoted by an encircled number 1, and the second terminal electrode of the TFT 50 is denoted by an encircled number 2. Furthermore, in the equivalent circuit diagram illustrated in FIG. 5, the first capacitance electrode of the capacitor 51 is denoted by number 1 with a square, and the second capacitance electrode of the capacitor 51 is denoted by number 2 with a square.

The gate electrode of the first TFT 50A is connected to the corresponding gate line 40g. The first terminal electrode of the first TFT 50A is connected to the corresponding source line 40s. The second terminal electrode of the first TFT 50A is connected to the corresponding second TFT 50B. The gate electrode of the second TFT 50B is connected to the second terminal electrode of the corresponding first TFT 50A. The first terminal electrode of the second TFT 50B is connected to the corresponding power source line 40p. The second terminal electrode of the second TFT 50B is connected to the corresponding third TFT 50C.

The gate electrode of the third TFT 50C is connected to the corresponding light emission control line 40e. The first terminal electrode of the third TFT 50C is connected to the second terminal electrode of the corresponding second TFT 50B. The second terminal electrode of the third TFT 50C is connected to the corresponding organic EL element 70 (pixel electrode 61). The first capacitance electrode of the capacitor 51 is connected to the power source line 40p. The second capacitance electrode of the capacitor 51 is connected to the second terminal electrode of the first TFT 50A and the gate electrode of the second TFT 50B.

### Disposition Configuration of Organic EL Elements and Pixel Circuits

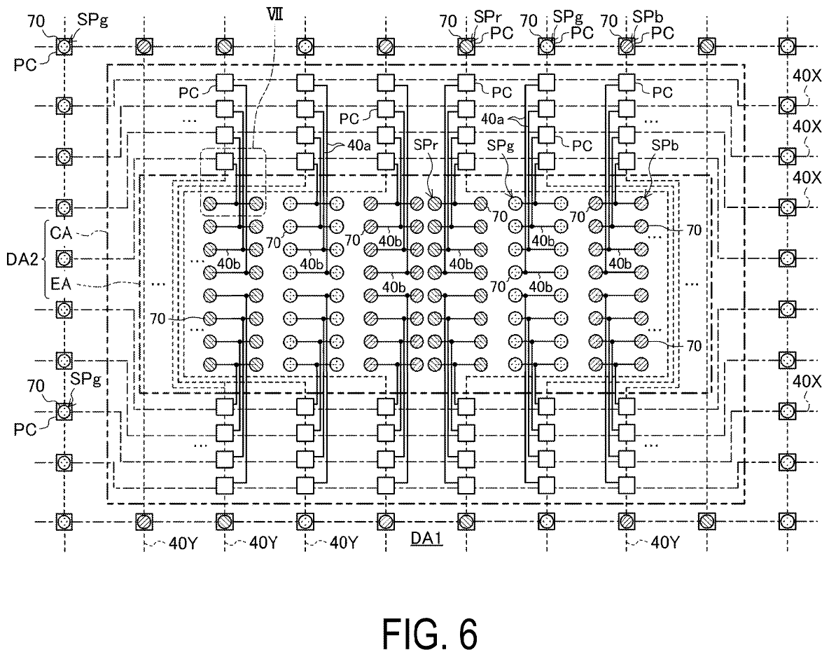

The arrangement relationship between the organic EL elements 70 and the pixel circuits PC in the second display region DA2 is different from that in the first display region DA1, and various wiring lines extend irregularly as illustrated in FIG. 6. FIG. 6 schematically illustrates the arrangement relationship between the organic EL elements 70 and the pixel circuits PC in the second display region DA2 and in the first display region DA1 around the second display region DA2.

In the schematic view illustrated in FIG. 6, the organic EL elements 70 are depicted by a circular symbol figure, and the pixel circuits PC are depicted by a rectangular symbol figure for the sake of convenience. In addition, in the schematic view of FIG. 6, the organic EL elements 70 configured to emit red light are hatched with leftward inclined lines, the organic EL elements 70 configured to emit green light are hatched with dots, and the organic EL elements 70 configured to emit blue light are hatched with rightward inclined lines.

In the schematic view of FIG. 6, the gate line 40g and the light emission control line 40e are indicated by a dash-dotted line as one representative wiring line (first metal line 40X) for the sake of convenience. Each of the gate line 40g and the light emission control line 40e extends in the same shape as the first metal lines 40X. In addition, in the schematic view of FIG. 6, the source line 40s and the power source line 40p are indicated by a broken line as one representative wiring line (second metal line 40Y) for convenience. Each of the source line 40s and the power source line 40p extends in the same shape as the second metal line 40Y.

In the first display region DA1, the pixel circuits PC are disposed at the positions overlapping the corresponding organic EL elements 70 in a plan view and in the vicinity close thereto. This is represented by the overlap of the organic EL elements 70 and the pixel circuits PC in FIG. 6. In other words, in the first display region DA1, each of the pixel circuits PC is provided at a position overlapping the subpixel SP formed by the organic EL element 70 corresponding to each of the pixel circuits PC.

As illustrated in FIG. 4, in the first display region DA1, the lower layer connection lines 40ra, the intermediate connection lines 40rb, and the upper layer connection lines 40rc constituting each of the connection lines 40r are located in a region overlapping the corresponding pixel electrode 61 in a plan view or in the periphery thereof, and are connected to each other in a local range. Accordingly, each connection line 40r is taken out over the third flattening film 58 from immediately above or around a predetermined TFT 50 (third TFT 50C), connecting the TFT 50 and the pixel electrode 61.

Each upper layer connection line 40rc in the first display region DA1 is configured as the transparent conductive layer TL2. The transparent conductive layer TL2 is a by-product accompanying the transparent wiring line layer TL1 to be described below. The transparent conductive layer TL2 is formed in an island shape for each subpixel SP of the first display region DA1. The transparent conductive layer TL2 is similar in shape to the pixel electrode 61 and has an area slightly smaller than that of the pixel electrode 61. Each of the pixel electrodes 61 in the first display region DA1 is provided to overlap the corresponding transparent conductive layer TL2.

Each of the pixel electrodes 61 completely covers the transparent conductive layer TL2 and also extends into the vicinity of the transparent conductive layer TL2. Each of the pixel electrodes 61 covers at least a part of the outer edge of the corresponding transparent conductive layer TL2. Each of the pixel electrodes 61 in the present example covers the entire outer edge (perimeter edge surface) of the corresponding transparent conductive layer TL2. The outer edge of each of the pixel electrodes 61 surrounds the entire outer edge of the corresponding transparent conductive layer TL2 in a plan view.

Each of the pixel electrodes 61 includes a first region PA1 and a second region PA2. The first region PA1 is a region of the pixel electrode 61 overlapping the transparent conductive layer TL2. The second region PA2 is a region of the pixel electrode 61 formed on the same layer as the transparent conductive layer TL2. In the present example, the second region PA2 of each of the pixel electrodes 61 is formed on the surface of the third flattening film 58 and has a frame shape extending to the entire circumference of the first region PA1. In addition, the inner peripheral portion of the second region PA2 is in contact with the perimeter edge surface of the transparent conductive layer TL2.

In the second display region DA2, the pixel circuits PC are disposed at separate positions where the pixel circuits PC do not overlap the corresponding organic EL elements 70 in a plan view as illustrated in FIG. 6. In the second display region DA2, a region in which the organic EL elements 70 forming the subpixels SP are disposed and a region in which a plurality of pixel circuits PC corresponding to the organic EL elements 70 are disposed are provided separately from each other.

Specifically, the second display region DA2 includes a light-emitting element region EA and a circuit disposition region CA. The light-emitting element region EA is provided in a central portion of the second display region DA2. The plurality of organic EL elements 70 are disposed in the light-emitting element region EA. The circuit disposition region CA is provided around the light-emitting element region EA. The plurality of pixel circuits PC are provided in the circuit disposition region CA. The pixel circuits PC control light emission of the organic EL elements 70 disposed in the light-emitting element region EA.

In the light-emitting element region EA, a plurality of sets of the organic EL elements 70 are disposed, where each set includes two organic EL elements 70 adjacent to each other. The two organic EL elements 70 forming each set are disposed side by side in the first direction X. These two organic EL elements 70 emit light of the same color. The pixel circuits PC in the circuit disposition region CA are provided for each set of the organic EL elements 70, and control light emission of the two organic EL elements 70 of the set together.

The connection lines 40r in the second display region DA2 are provided for each set of a set of organic EL elements 70 and a pixel circuit PC. The connection lines 40r connect the organic EL elements 70 of each set to the pixel circuit PC, strictly speaking, to a predetermined TFT 50 (third TFT 50C). The plurality of upper layer connection lines 40rc in the second display region DA2 is connected to the two organic EL elements 70 forming the corresponding set, respectively, and connects these two organic EL elements 70 to each other. The two organic EL elements 70 forming each set are connected to a common upper layer connection line 40rc.

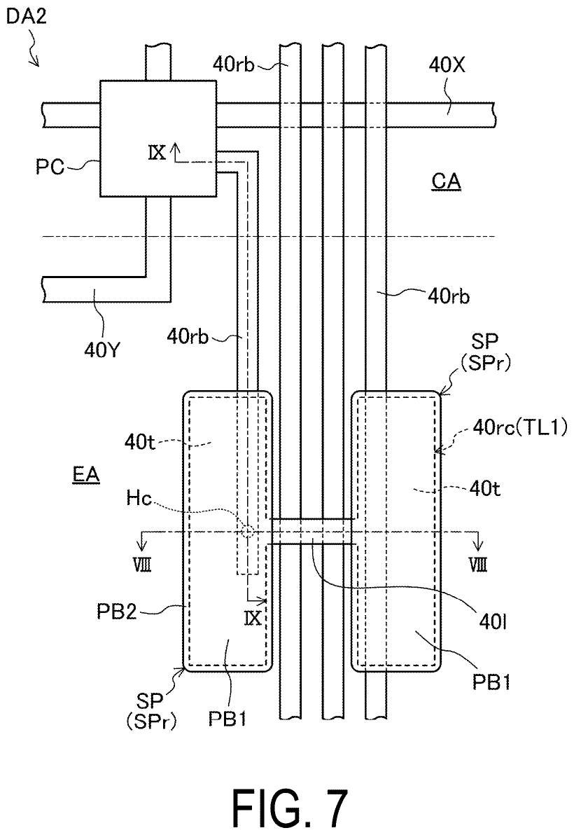

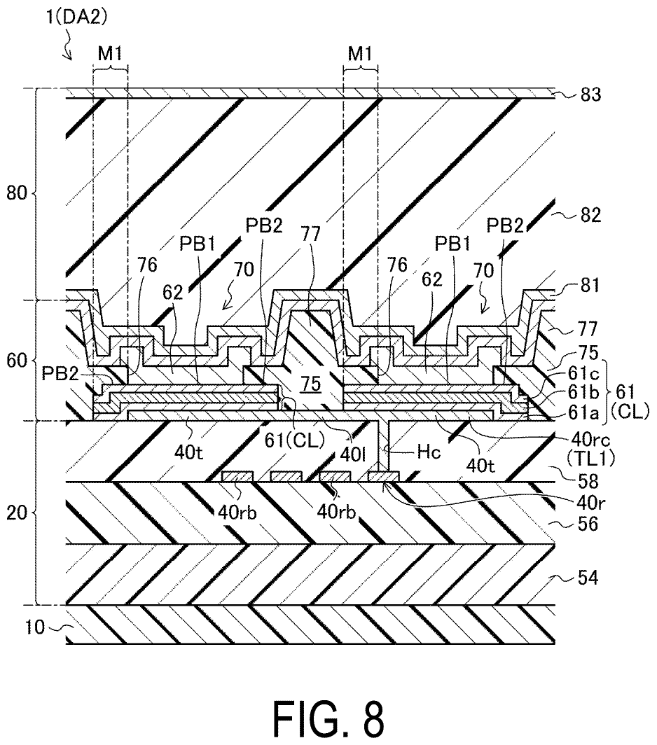

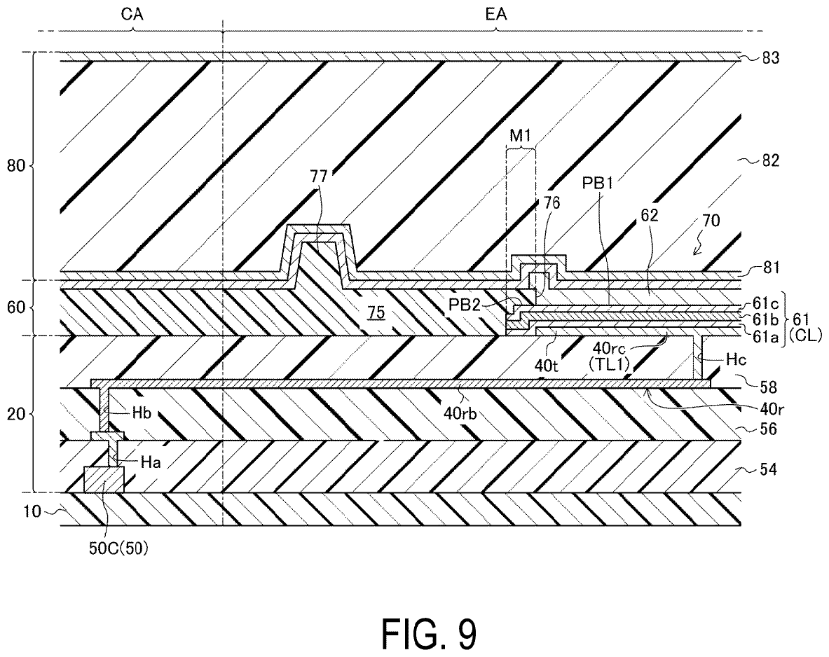

Each of the plurality of intermediate connection lines 40rb in the second display region DA2 is drawn out from the light-emitting element region EA to the circuit disposition region CA, and is connected to a predetermined TFT 50 (the third TFT 50C) via the lower layer connection line 40rain the circuit disposition region CA as illustrated in FIG. 9. As illustrated in FIG. 7, some of the intermediate connection lines 40rb and the upper layer connection lines 40rc that are not connected to each other intersect each other and extend in a plan view in the second display region DA2. The third flattening film 58 is sandwiched in the intersection of the intermediate connection line 40rband the upper layer connection line 40rcas illustrated in FIG. 8.

Each upper layer connection line 40rcin the second display region DA2 includes a pair of electrode terminal portions 40t and a coupling line portion 401. The pair of electrode terminal portions 40 t are separately provided at both ends of the upper layer connection line 40rc, and are connected to the pixel electrodes 61 of different organic EL elements 70. The coupling line portion 401 connects the pair of electrode terminal portions 40t. Each of the electrode terminal portions 40t is similar in shape to the corresponding pixel electrode 61 and has an area slightly smaller than that of the pixel electrode 61. The upper layer connection line 40rcis configured as the transparent wiring line layer TL1. That is, each of the connection lines 40r in the second display region DA2 includes the transparent wiring line layer TL1 formed on the same layer (third flattening film 58) as the pixel electrodes 61.

Each of the pixel electrodes 61 in the second display region DA2 is provided to overlap a portion constituting the electrode terminal portion 40t in the corresponding transparent wiring line layer TL1. The pixel electrodes 61 cover the portions of the transparent wiring line layer TL1 constituting the electrode terminal portions 40t, and also extend to the vicinity of the portions constituting the electrode terminal portions 40t. The pixel electrodes 61 cover a part of the outer edge of the transparent wiring line layer TL1, in this example, the entire outer edges (perimeter edge surfaces) of the portions constituting the electrode terminal portions 40t. In addition, the outer edges of the pixel electrodes 61 surround the outer edges of the portions constituting the electrode terminal portions 40t in the transparent wiring line layer TL1 in a plan view.

Each of the pixel electrodes 61 includes a first region PB1 and a second region PB2. The first region PB1 is a region of the pixel electrode 61 overlapping the transparent wiring line layer TL1. The second region PB2 is a region of the pixel electrode 61 formed on the same layer as the transparent wiring line layer TL1. In the present example, the second region PB2 of each of the pixel electrodes 61 is formed on the surface of the third flattening film 58 and has a frame shape extending to the entire circumference of the first region PB1. In addition, the inner peripheral portion of the second region PB2 is in contact with the perimeter edge surface of the transparent wiring line layer TL1.

The transparent wiring line layer TL1 and the transparent conductive layer TL2 are formed of the same material in the same layer. The transparent wiring line layer TL1 and the transparent conductive layer TL2 of the present example are formed of a crystallized transparent conductive material, in the present example, indium tin oxide (ITO) as described above, and have a relatively high optical transparency. Indium tin oxide (ITO) has the property of being less corroded by a predetermined etching solution after being crystallized while being corroded by the etching solution before being crystallized. Here, the “predetermined etching solution” includes an etching solution (ITO etching solution in this example) used for patterning the transparent wiring line layer TL1 and the transparent conductive layer TL2, and an etching solution (PAN-based etching solution in this example) used for patterning the pixel electrodes 61 (the first transparent electrode layer 61a, the reflective electrode layer 61b, and the second transparent electrode layer 61c).

Each of the first metal lines 40X corresponding to the plurality of subpixels SP in the second display region DA2 extends via the outer side of the group of the organic EL elements 70 disposed in the light-emitting element region EA as illustrated in FIG. 6. Each of the first metal lines 40X extends in the circuit disposition region CA while being away from the light-emitting element region EA, and is connected to the pixel circuits PC (the second terminal electrodes of the third TFT 50C) in the circuit disposition region CA. In addition, each of the second metal lines 40Y corresponding to the plurality of subpixels SP in the second display region DA2 extends via the outer side of the group of the organic EL elements 70 disposed in the light-emitting element region EA.

As described above, in the second display region DA2, the connection lines 40r (the intermediate connection lines 40rb and the upper layer connection lines 40rc), the first metal lines 40X, and the second metal lines 40Y are designed to avoid reducing transmittance with respect to light from the front face side to the back face side in the light-emitting element region EA.

### Operation of Organic EL Display Device

In the organic EL display device 1, first, a corresponding light emission control line 40e is selected for each subpixel SP, and an emission signal indicating an inactive state is input to the third TFT 50C via the light emission control line 40e. As a result, the third TFT 50C transitions to an OFF state, causing the organic EL element 70 to enter a non-light emission state.

Then, the gate line 40g corresponding to the organic EL element 70 in the non-light emission state is selected, and a gate signal indicating an active state is input to the first TFT 50A via the gate line 40g. As a result, the first TFT 50A enters an ON state. When the first TFT 50A enters the ON state, a predetermined voltage corresponding to the source signal transmitted via the source line 40s is applied to the second TFT 50B and written in the capacitor 51.

Thereafter, the corresponding light emission control line 40e is selected, and an emission signal indicating an active state is input to the third TFT 50C. As a result, the third TFT 50C enters an ON state. When the third TFT 50C enters the ON state, a drive current corresponding to the voltage applied to the gate electrode of the second TFT 50B is supplied from the power source line 40p to the organic EL element 70.

In this way, in the organic EL display device 1, the organic EL element 70 (light-emitting layer) emits light at a luminance corresponding to the drive current, whereby image display is performed in each subpixel SP. Note that, since the voltage applied to the gate electrode of the second TFT 50B is preserved by the capacitor 51 even when the first TFT 50A in an OFF state, the light emission of the organic EL element 70 is maintained for each of the subpixels SP until the gate signal of the next frame is input.

In addition, in the organic EL display device 1, external light is transmitted from the front face side to the back face side in the second display region DA2. The external light transmitted through the second display region DA2 is incident on the light receiving unit of the camera 3. The camera 3 receives external light transmitted through the second display region DA2 and converts the external light into an electric signal using an image sensor. As a result, in the organic EL display device 1, image capturing is performed by the camera 3 with the front side of the screen as the target (subject side).

### Manufacturing Method of Organic EL Display Device

To manufacture the organic EL display device 1, first, the substrate layer 10 is formed by applying an organic resin material onto the surface of a glass substrate 200 and subjected to a baking treatment. Subsequently, the TFT layer 20, the light-emitting element layer 60, and the sealing film 80 are sequentially formed on the substrate layer 10 using a known film formation method such as a chemical vapor deposition (CVD) method, sputtering, or a vacuum vapor deposition method, a known coating method such as a spin coating method or an ink-jet method, and a known patterning technique such as photolithography.

Then, the glass substrate 200 is peeled off from the substrate layer 10 by irradiating the rear surface of the substrate layer 10 with a laser beam from the glass substrate 200 side. Subsequently, a polarizer, a cover panel, or the like is bonded to the surface of the sealing film 80. In addition, a protection film 11 is bonded to the back face of the substrate layer 10. Furthermore, the display control circuit is mounted by connecting the wiring line substrate CB to the terminal portion TP. Thereafter, the organic EL display device 1 is accommodated in the housing together with the camera 3, and the camera 3 is installed at a position overlapping the second display region DA2 in a plan view on the back face side of the organic EL display device 1.

The organic EL display device 1 can be manufactured in the manner described above.

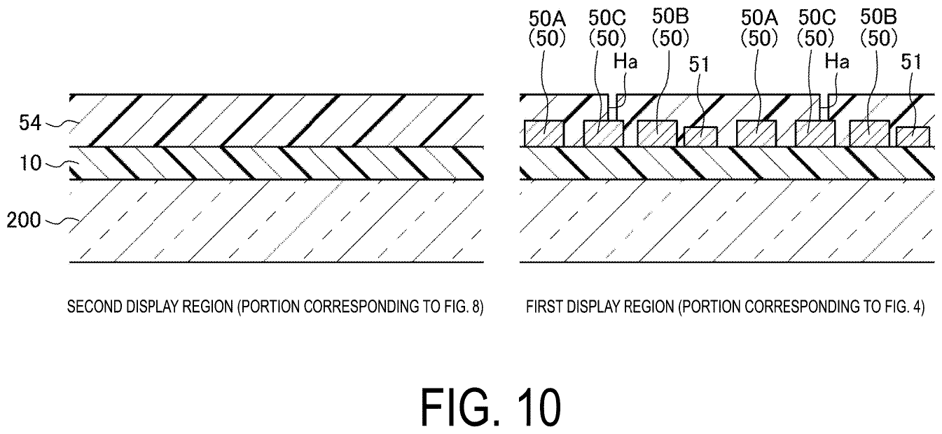

In the step of forming the TFT layer 20, after a plurality of TFTs 50 and capacitors 51 are formed on the substrate layer 10 on the surface of the glass substrate 200, acrylic or polyimide photosensitive resins or photosensitive SOG materials are applied by using a method, for example, spin coating method or slit coating method. Next, the applied film is subjected to pre-baking, exposure, development, and post-baking. As a result, the first flattening film 54 (having a thickness of, for example, about 0.5 μm to 3.0 μm) having the first contact holes Ha is formed as illustrated in FIG. 10.

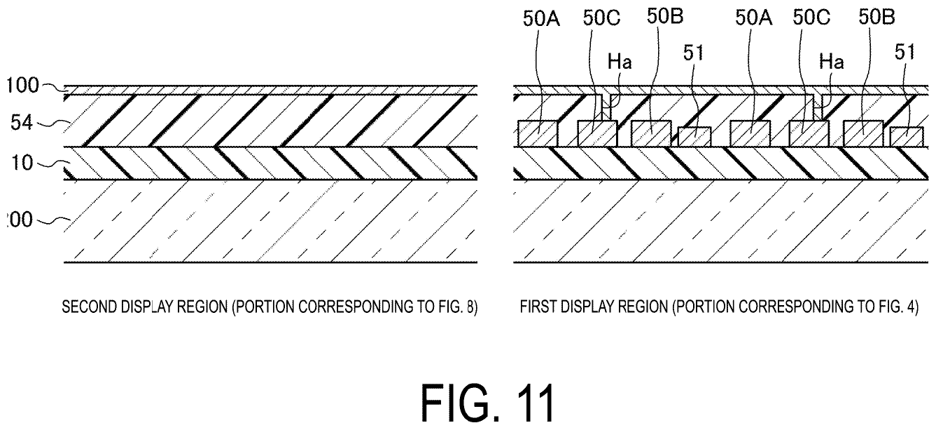

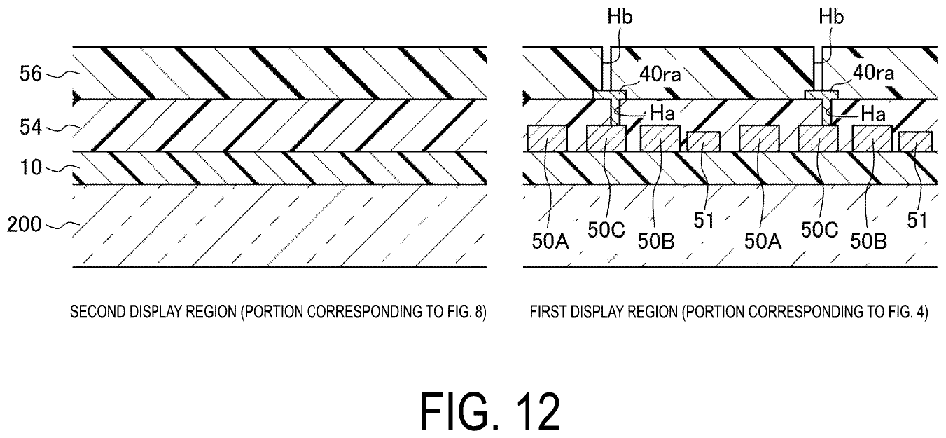

Subsequently, a titanium film is formed on the substrate on which the first flattening film 54 has been formed by using, for example, a sputtering method. As a result, the first metal film 100 (having a thickness of about, for example, 100 nm to 500 nm) is formed as illustrated in FIG. 11. Here, to form the first metal film 100, instead of the titanium film, a molybdenum film may be formed, or a titanium film, an aluminum film, and a titanium film may be sequentially formed. Next, the first metal film 100 is patterned to form the lower layer connection lines 40ra (see FIG. 12). The patterning of the first metal film 100 is performed by using a method, for example, wet etching or dry etching using an etching solution corresponding to a metal material such as a known titanium etching solution.

Next, an acrylic or polyimide photosensitive resin or a photosensitive SOG material is applied on the substrate on which the lower layer connection lines 40ra have been formed, by using a method, for example, spin coating method or slit coating method. Next, the applied film is subjected to pre-baking, exposure, development, and post-baking. As a result, the second flattening film 56 (having a thickness of, for example, about 0.5 μm to 30 μm) having the second contact holes Hb is formed as illustrated in FIG. 12.

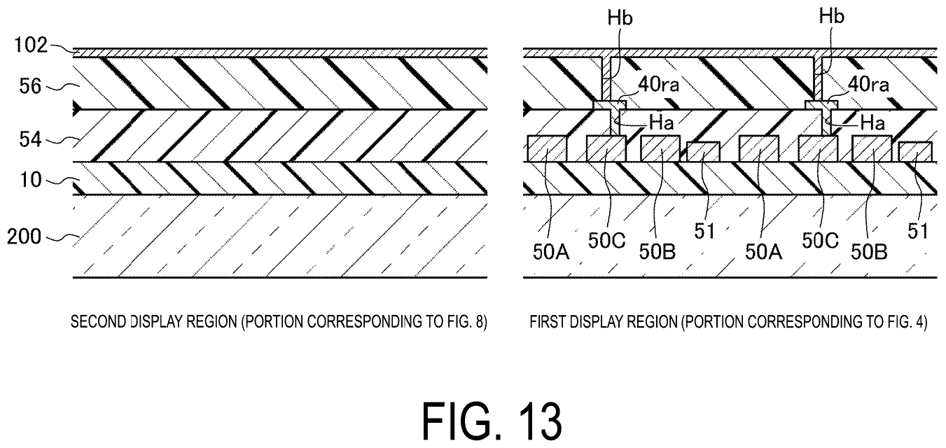

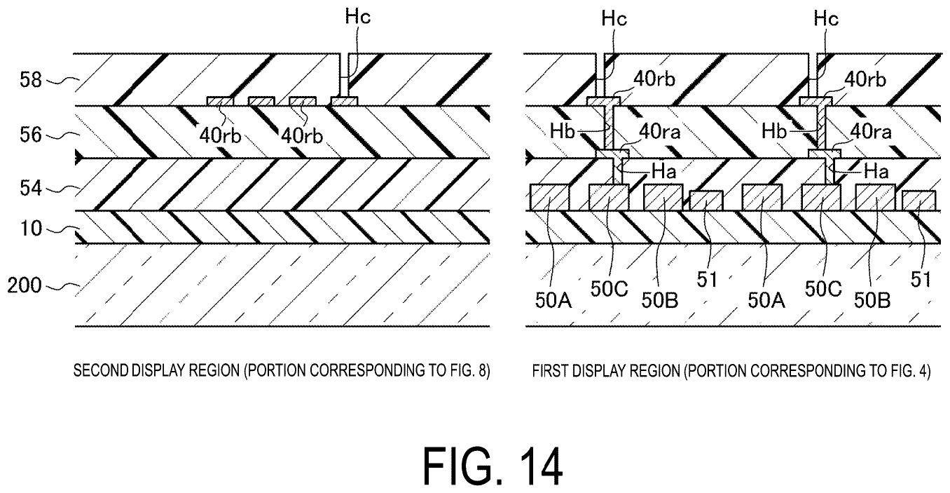

Next, an indium tin oxide film is formed on the substrate on which the second flattening film 56 has been formed using, for example, a sputtering method. As a result, the first transparent conductive film 102 (having a thickness of, for example, about 50 nm to 150 nm) is formed as illustrated in FIG. 13. Here, to form the first transparent conductive film 102, an indium-zinc oxide film or an indium gallium zinc oxide film may be formed. Next, the first transparent conductive film 102 is patterned to form the intermediate connection lines 40rb (see FIG. 14). The patterning of the first transparent conductive film 102 is performed by using, for example, wet etching using an etching solution corresponding to a transparent conductive material such as a known ITO etching solution.

Next, an acrylic or polyimide photosensitive resin or a photosensitive SOG material is applied onto the substrate on which the intermediate connection lines 40rb have been formed, using a method, for example, spin coating method or slit coating method. Next, the applied film is subjected to pre-baking, exposure, development, and post-baking. As a result, the third flattening film 58 (having a thickness of, for example, about 0.5 μm to 3.0 μm) having the third contact holes Hc is formed as illustrated in FIG. 14.

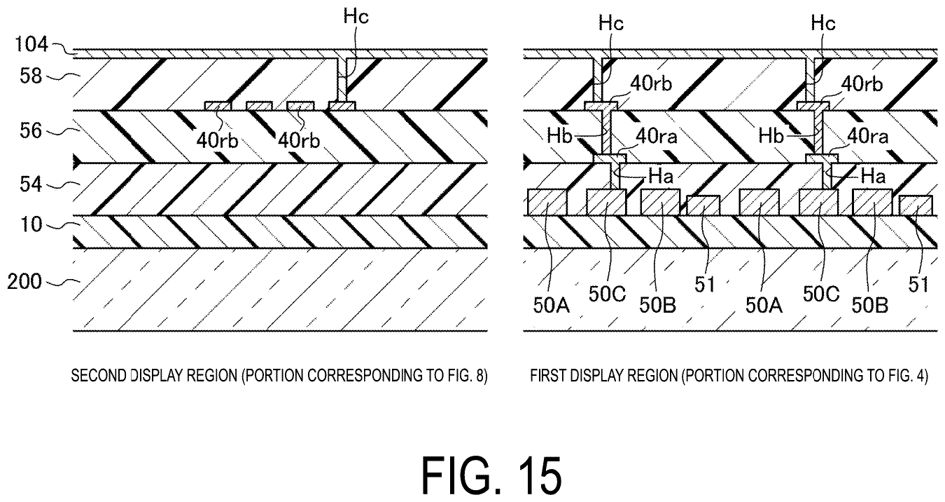

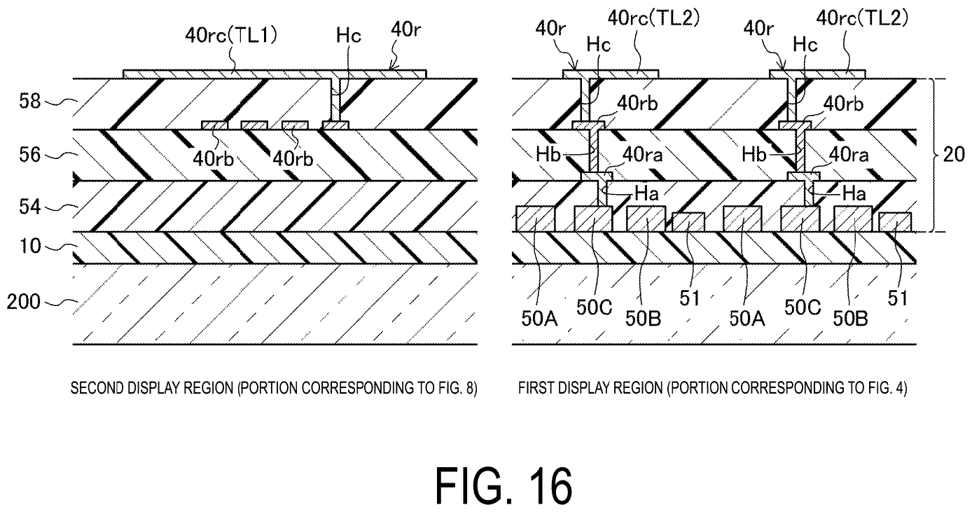

Next, an indium tin oxide film is formed on the substrate on which the third flattening film 58 has been formed using, for example, a sputtering method. As a result, the second transparent conductive film 104 (having a thickness of, for example, about 50 μm to 150 μm) is formed as illustrated in FIG. 15. Here, to form the second transparent conductive film 104, an indium-zinc oxide film or an indium gallium zinc oxide film may be formed. Subsequently, the second transparent conductive film 104 is patterned to form the upper layer connection lines 40rc (the transparent wiring line layer TL1 and the transparent conductive layer TL2) as illustrated in FIG. 16. The patterning of the second transparent conductive film 104 is performed by using, for example, wet etching using an etching solution corresponding to a transparent conductive material such as a known ITO etching solution.

Next, the substrate on which the upper layer connection lines 40rc have been formed is subjected to an annealing process, for example, at a temperature of approximately 200° C. to 250° C. for approximately 30 minutes to 120 minutes. Through this annealing process, the lower layer connection lines 40ra, the intermediate connection lines 40rb, and the upper layer connection lines 40rc (the transparent wiring line layer TL1 and the transparent conductive layer TL2) are crystallized. With this operation, the conductivity and the optical transparency of the lower layer connection lines 40ra, the intermediate connection lines 40rb, and the upper layer connection lines 40rc (the transparent wiring line layer TL1 and the transparent conductive layer TL2) are enhanced. In addition, the crystallization makes the transparent wiring line layer TL1 and the transparent conductive layer TL2 resistant to a PAN-based etching solution used for patterning of the pixel electrodes 61 to be performed later.

The TFT layer 20 can be formed as described above.

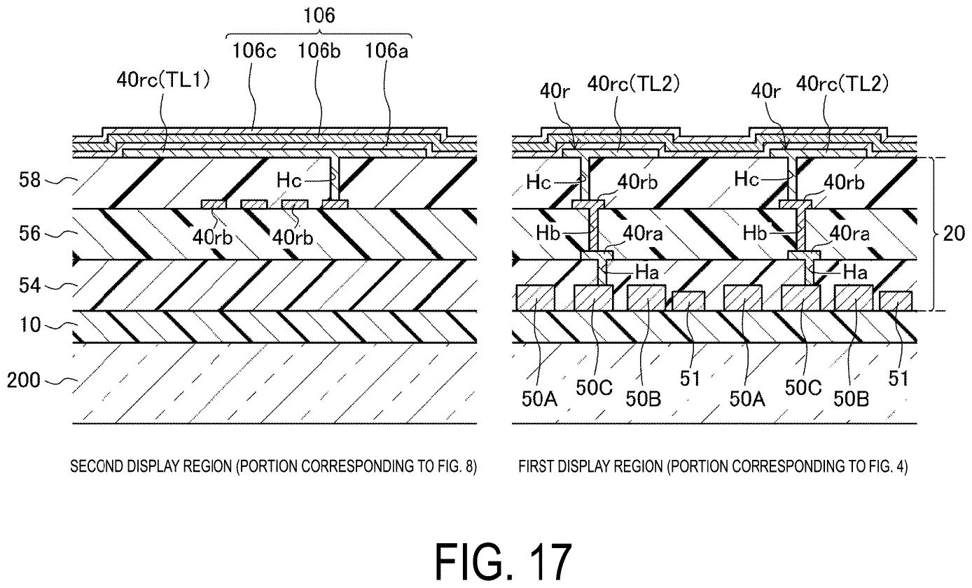

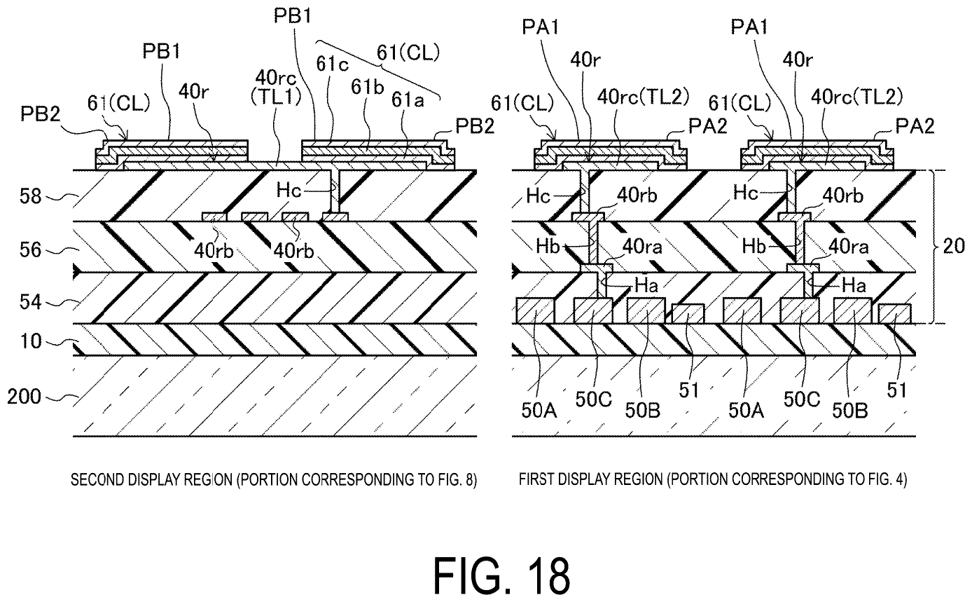

In the step of forming the light-emitting element layer 60, an indium tin oxide film 106a (having a thickness of for example, about 5 nm to 100 nm), a silver film 106 b (having a thickness of, for example, about 50 nm to 200 nm), and an indium tin oxide film 106 c (having a thickness of, for example, about 5 nm to 100 nm) are formed in this order on the substrate on which the upper layer connection lines 40rc have been formed by using, for example, a sputtering method. As a result, a second metal film 106 is formed as illustrated in FIG. 17. Here, to form the second metal film 106, an indium zinc oxide film or an indium gallium zinc oxide film may be formed, instead of the indium tin oxide films 106a and 106c. In addition, instead of the silver film 106b, a silver alloy film, an aluminum film, or an aluminum alloy film may be formed. Subsequently, the second metal film 106 is patterned to form the pixel electrodes 61 as illustrated in FIG. 18.

The patterning of the second metal film 106 is performed by using wet etching. In this wet etching, a PAN-based etching solution in which phosphoric acid, nitric acid, and acetic acid are mixed is used as an etching solution. At this time, each of the upper layer connection lines 40rc (transparent wiring line layer TL1) in the second display region DA2 is exposed to the PAN-based etching solution. However, since the upper layer connection lines 40rc (transparent wiring line layer TL1) are crystallized beforehand and have resistance, the upper layer connection lines 40rc are not corroded or are less corroded by the etching solution, and may remain partially exposed from the pixel electrodes 61.

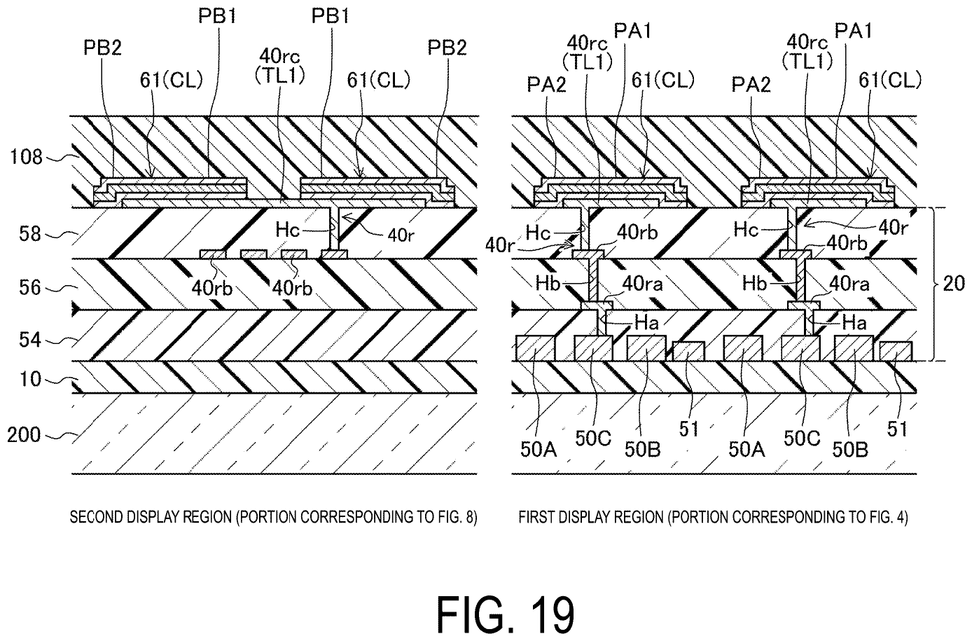

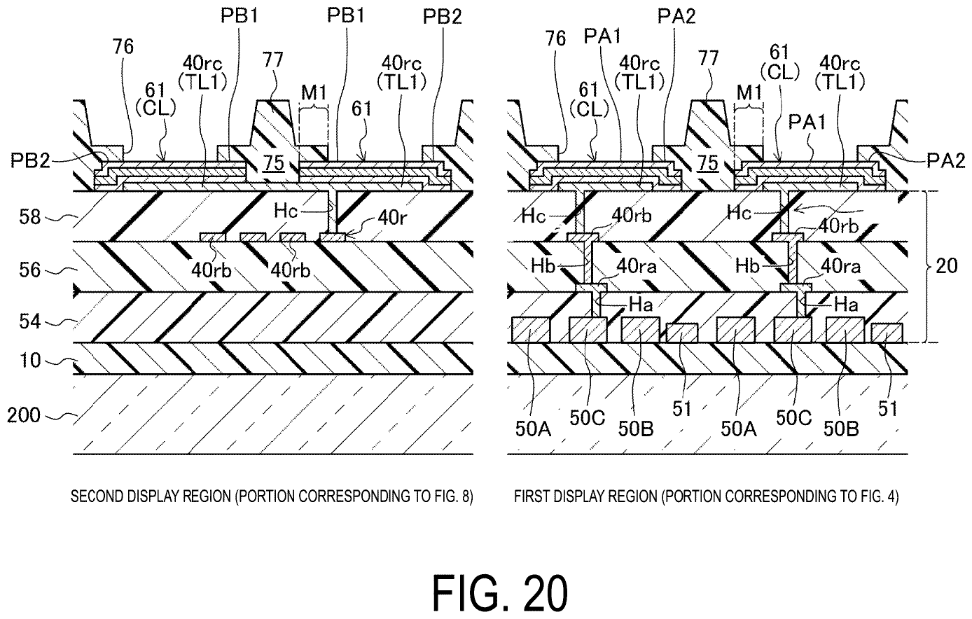

Next, a polyimide photosensitive resin is applied on the substrate on which the pixel electrodes 61 have been formed by using a method, for example, spin coating method or slit coating method, as illustrated in FIG. 19. Then, the applied film 108 is subjected to pre-baking, exposure, development, and post-baking. As a result, the edge covers 75 having the photo spacers 77 are formed as illustrated in FIG. 20. Then, the organic EL layers 62 and the common electrode 63 are sequentially formed on the substrate on which the edge covers 75 have been formed by using a known method.

In this manner, the light-emitting element layer 60 may be formed.

### Features of First Embodiment

In the organic EL display device 1 according to the first embodiment, the connection lines 40r provided in the second display region DA2 includes the transparent wiring line layer TL1 (upper layer connection lines 40rc) having optical transparency. This makes it possible to raise the transmittance of external light received by the camera 3 in the second display region DA2. In addition, while the pixel electrodes 61 in the second display region DA2 are provided to overlap the transparent wiring line layer TL1, the pixel electrodes cover a part of the outer edge of the transparent wiring line layer TL1. In the portion of the outer edge of the transparent wiring line layer TL1 covered with the pixel electrodes 61, the margin M1 between both patterns of the pixel electrodes 61 and the openings 76 of the edge covers 75 is required to be considered as an alignment margin for the individual organic EL elements 70, and the margin between both patterns of the transparent wiring line layer TL1 and the pixel electrodes 61 does not need to be secured. Accordingly, in the second display region DA2, the distance to be secured between adjacent pixel electrodes 61 can be shortened. Thereby, the organic EL display device 1 can produce display images with higher definition.

In the organic EL display device 1 according to the first embodiment, the pixel electrodes 61 in the first display region DA1 are provided to overlap the transparent conductive layer TL2 and cover the entire circumference of the outer edge of the transparent conductive layer TL2. In the portion of the outer edge of the transparent conductive layer TL2 covered with the pixel electrodes 61, the margin M1 between both patterns of the pixel electrodes 61 and the openings 76 of the edge covers 75 is required to be considered as an alignment margin for the individual organic EL elements 70, and the margin between both patterns of the transparent conductive layer TL2 and the pixel electrodes 61 does not need to be secured. Accordingly, in the first display region DA1, the distance to be secured between adjacent pixel electrodes 61 can be shortened. Thereby, the organic EL display device 1 can produce display images with higher definition.

In the organic EL display device 1 according to the first embodiment, the transparent wiring line layer TL1 is formed of a crystallized transparent conductive material. The transparent conductive material has a property of being less corroded by a predetermined etching solution after being crystallized while being corroded by the etching solution before being crystallized. When the predetermined etching solution is used to pattern a film or layer positioned above the transparent wiring line layer TL1 and a transparent conductive material is crystallized, the transparent conductive material is less corroded even when exposed to the etching solution, and thus the material is a suitable material for the transparent wiring line layer TL1.

In the organic EL display device 1 according to the first embodiment, the transparent wiring line layer TL1 is made of indium tin oxide (ITO). Indium tin oxide (ITO) can be used as a specific material for the transparent wiring line layer TL1 because it exhibits excellent properties with respect to the above-described etching solution.

In the organic EL display device 1 according to the first embodiment, each of the pixel electrodes 61 has a layered structure including the first transparent electrode layer 61a, the reflective electrode layer 61b, and the second transparent electrode layer 61c. In addition, the transparent wiring line layer TL1 has a property of being less corroded by a PAN-based etching solution used to pattern the first transparent electrode layer 61a, the reflective electrode layer 61b, and the second transparent electrode layer 61c. According to this configuration, the first transparent electrode layer 61a, the reflective electrode layer 61b, and the second transparent electrode layer 61c can be collectively etched while leaving the transparent wiring line layer TL1. As a result, the process for forming the pixel electrode 61 can be reduced. This is advantageous for reducing the cost of the organic EL display device 1.

In the organic EL display device 1 according to the first embodiment, the connection lines 40r include the intermediate connection lines 40rb in addition to the upper layer connection lines 40ra. The upper layer connection lines 40ra and the intermediate connection lines 40rb are formed in different layers. Accordingly, the layout of the upper layer connection lines 40ra and the intermediate connection lines 40rb can be designed as an arrangement in which the lines intersect each other and extend in a plan view. Furthermore, the intermediate connection lines 40rb also have optical transparency. This is advantageous to enhancement in the transmittance of external light received by the camera 3 in the second display region DA2.

In the organic EL display device 1 of the first embodiment, a plurality of organic EL elements 70 in the second display region DA2 are disposed in the light-emitting element region EA, and a plurality of pixel circuits PC for controlling light emission of the organic EL elements 70 in the light-emitting element region EA are disposed around the light-emitting element region EA. According to this configuration, it is unnecessary to provide the pixel circuits PC in the light-emitting element region EA. Thus, in the light-emitting element region EA, light from the front face side of the display region DA is suitably transmitted to the back face side, thereby making it possible to secure external light received by the camera 3. This is advantageous for the camera 3 to exhibit functions.

In the organic EL display device 1 according to this embodiment, the pixel circuits PC are provided for each set of organic EL elements 70 in which two or more organic EL elements 70 are grouped into one set. In addition, light emission of the two or more organic EL elements 70 forming the set is controlled by a common pixel circuit PC. According to this configuration, the number of pixel circuits PC can be smaller than the number of organic EL elements 70 in the second display region DA2. This is advantageous to enhancement in the transmittance of external light received by the camera 3 in the second display region DA2.

### Second Embodiment

An organic EL display device 1 according to a second embodiment differs from that of the first embodiment in terms of the configuration of the connection between the pixel electrodes 61 and the TFTs 50 in the first display region DA1. Note that the present embodiment is configured in a similar manner to the first embodiment with respect to the organic EL display device 1, except that the configuration of the connection between the pixel electrodes 61 and the TFTs 50 in the first display region DA1 is different from that in the first embodiment.

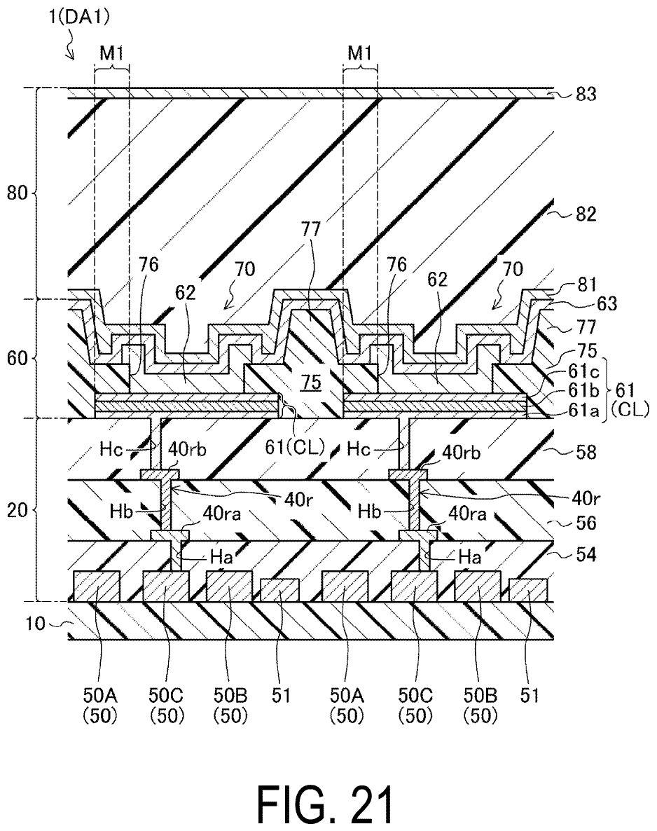

In the organic EL display device 1 according to the second embodiment, the pixel electrodes 61 in the first display region DA1 are connected to the intermediate connection lines 40rb via the third contact holes Hc formed in the third flattening film 58 as illustrated in FIG. 21. While the upper layer connection lines 40rc are provided in the second display region DA2 as in the first embodiment (see FIGS. 8 and 9), the upper layer connection lines are not provided in the first display region DA1. All the pixel electrodes 61 in the first display region DA1 are formed on the surface of the third flattening film 58 and are directly connected to the intermediate connection lines 40rb.

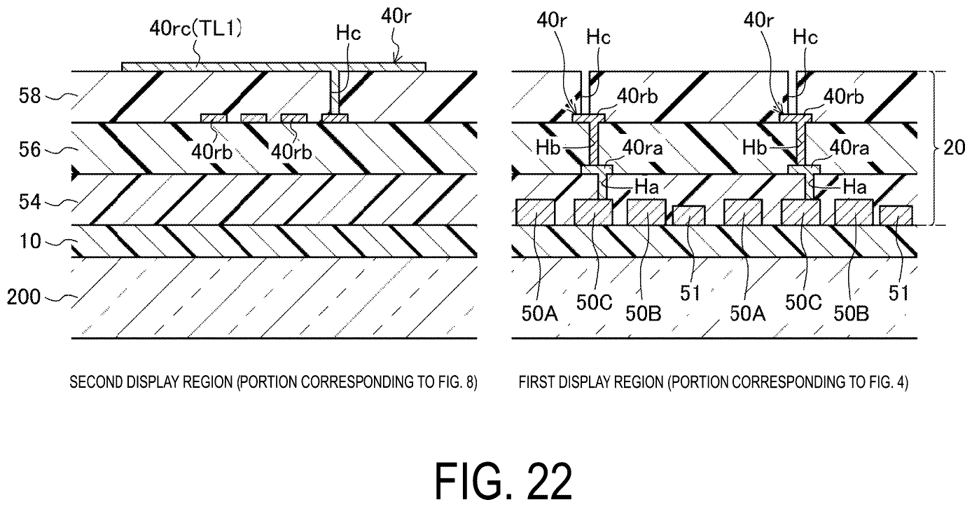

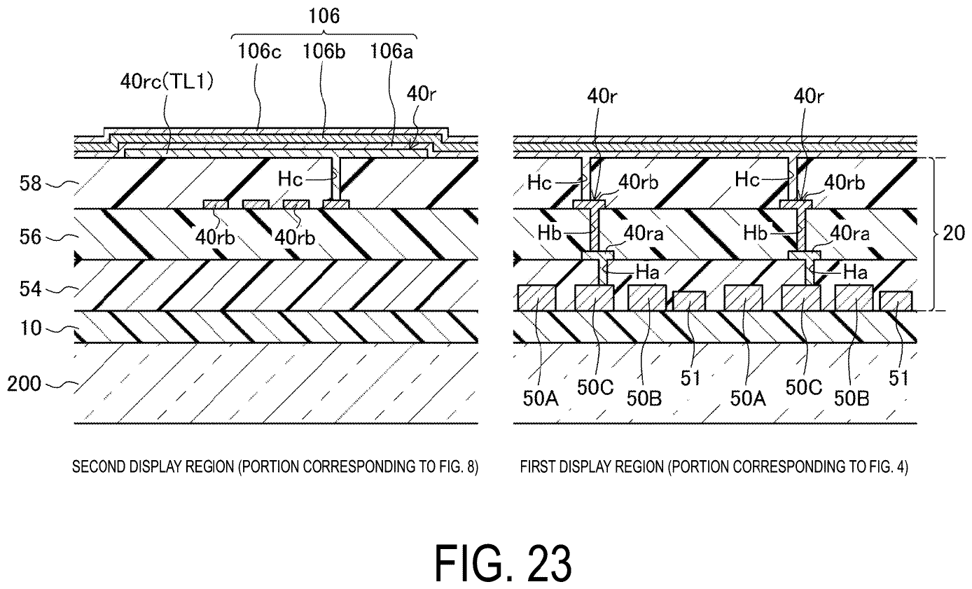

To manufacture the organic EL display device 1 of the second embodiment, when the second transparent conductive film 104 is patterned in the step of forming the TFT layer 20, the upper layer connection lines 40rc are formed only in the second display region DA2, and the second transparent conductive film 104 is removed in the first display region DA1 as illustrated in FIG. 22. In the subsequent step of forming the light-emitting element layer 60, the second metal film 106 is formed in the same manner as in the first embodiment as illustrated in FIG. 23. Then, as in the first embodiment, the second metal film 106 is patterned to form the pixel electrodes 61.

Features of Second Embodiment In the organic EL display device 1 according to the second embodiment, no upper layer connection lines 40rc are provided in the first display region DA1. According to this configuration, the structure of each subpixel SP in the first display region DA1 can be made close to that of an organic EL display device of a type not including the second display region DA2. This is advantageous for achieving high definition of display images in the organic EL display device 1 with an in-camera.

### Third Embodiment

An organic EL display device 1 according to a third embodiment differs from that of the first embodiment in terms of the configuration of the connection between the pixel electrodes 61 and the TFTs 50 in the first display region DA1. Note that the present embodiment is configured in a similar manner to the first embodiment with respect to the organic EL display device 1, except that the configuration of the connection between the pixel electrodes 61 and the TFTs 50 in the first display region DA1 is different from that in the first embodiment.

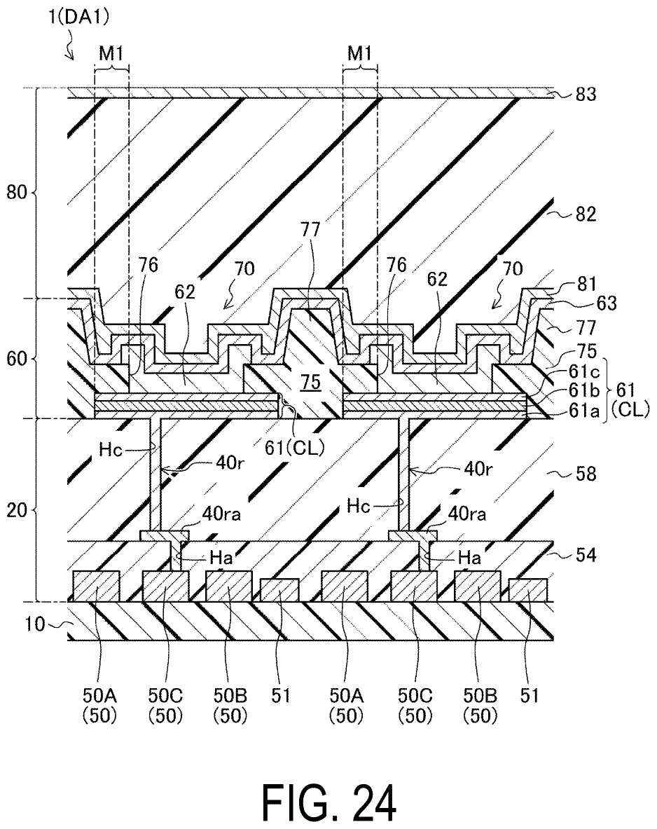

In the organic EL display device 1 according to the third embodiment, the pixel electrodes 61 in the first display region DA1 are connected to the lower layer connection lines 40ra via the third contact holes Hc formed in the third flattening film 58 as illustrated in FIG. 24. While the upper layer connection lines 40rc, the second flattening film 56, and the intermediate connection lines 40rb are provided in the second display region DA2 as in the first embodiment (see FIGS. 8 and 9), the lines and the films are not provided in the first display region DA1. The third flattening film 58 in the first display region DA1 is as thick as the layered film of the second flattening film 56 and the third flattening film 58 in the second display region DA2.

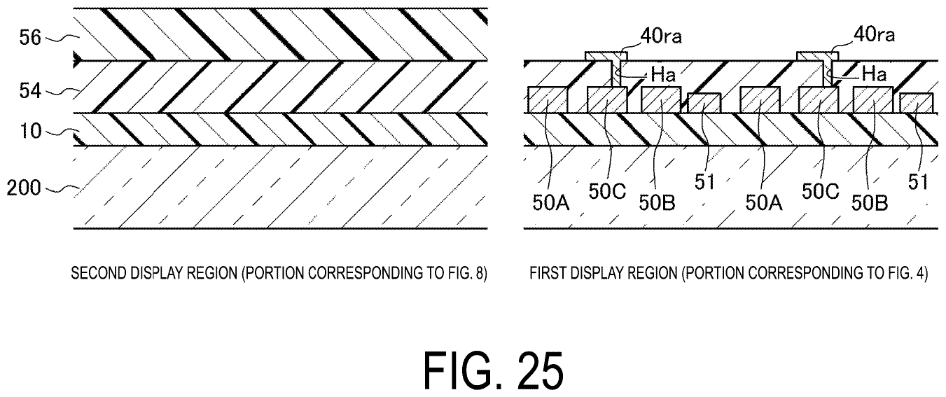

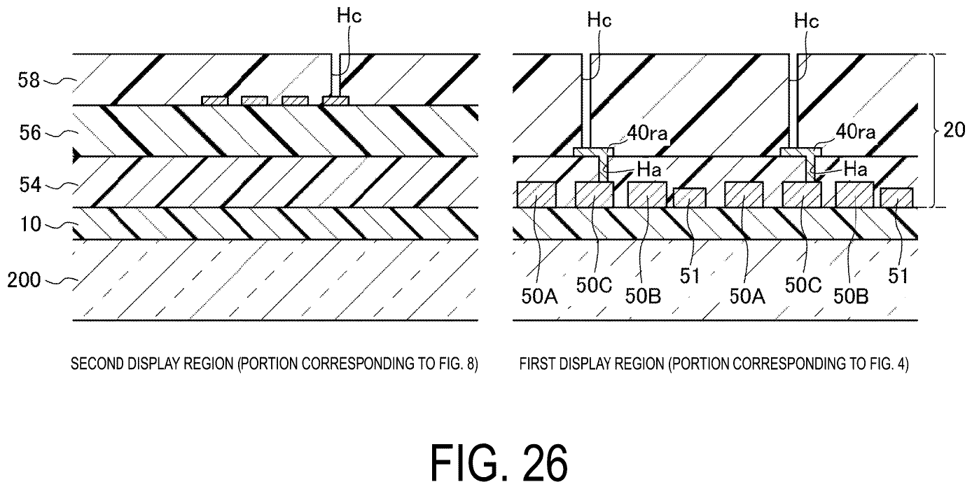

To manufacture the organic EL display device 1 of the third embodiment, when the second flattening film 56 is formed in the step of forming the TFT layer 20, the second flattening film 56 is formed only in the second display region DA2, and the applied film is removed in the first display region DA1 as illustrated in FIG. 25. Then, the third flattening film 58 is formed to have substantially the same surface height in the first display region DA1 and the second display region DA2 as illustrated in FIG. 26. At this time, when it is necessary to adjust the thicknesses of the third flattening film 58 in the first display region DA1 and the second display region DA2, a gray-tone mask or a half-tone mask may be used at the time of exposure of the applied film.

### Features of Third Embodiment

In the organic EL display device 1 according to the third embodiment, the upper layer connection lines 40rc, and further the second flattening film 56 and the intermediate connection lines 40rb are not provided in the first display region DA1. According to this configuration, the structure of each subpixel SP in the first display region can be made the same as that of an organic EL display device of a type that does not include the second display region DA2. This is advantageous for achieving high definition of display images in the organic EL display device 1 with an in-camera.

### Other Embodiments

Although each of the pixel electrodes 61 in the first display region DAI covers the entire transparent conductive layer TL2 and covers the entire circumference of the outer edge of the transparent conductive layer TL2 in the first embodiment, no such limitation is intended. Each of the pixel electrodes 61 in the first display region DA1 may cover only a part of the outer edge of the transparent conductive layer TL2.

Although the upper layer connection lines 40rc (transparent conductive layer TL2) are not provided in the first display region DA1 in the third embodiment, the configuration is not limited thereto. In the organic EL display device 1 according to the third embodiment, the upper layer connection lines 40rc (the transparent conductive layer TL2) may also be provided in the first display region DA1 as in the first embodiment.

Although the transparent conductive layer TL2 constitutes the upper layer connection lines 40rc and is included in the TFT layer 20 in the first embodiment, no such limitation is intended. The transparent conductive layer TL2 may be regarded as a part of the pixel electrodes 61 (that is, included in the light-emitting element layer 60).

Although each of the pixel electrodes 61 is formed by layering the first transparent electrode layer 61a, the reflective electrode layer 61b, and the second transparent electrode layer 61c in this order in the first to third embodiments, no such limitation is intended. Each pixel electrode 61 may be configured by two or fewer conductive layers or may be configured by four or more conductive layers.

Although two of the plurality of organic EL elements 70 provided in the light-emitting element region EA form one set and the organic EL elements 70 are designed to be connected to each other via the upper layer connection line 40rcin each set in the first to third embodiments, no such limitation is intended. Three or more of the plurality of organic EL elements 70 in the light-emitting element region EA may form one set, and the organic EL elements 70 may be connected to each other via the upper layer connection line 40rcin each set.

Two or more of the plurality of organic EL elements 70 provided in the light-emitting element region EA may be allowed not to form one set. That is, the plurality of organic EL elements 70 in the light-emitting element region EA may be allowed not to be connected to each other and may be individually controlled. In this case, in the circuit disposition region CA, an individual pixel circuit PC is provided for each organic EL element 70, and each organic EL element 70 is connected to an individual pixel circuit PC via the connection lines 40r.

Although the organic EL layers 62 are provided in each of the subpixels SP individually in the first to third embodiments, no such limitation is intended. The organic EL layers 62 may be continuously provided to be common in the plurality of subpixels SP. In this case, the organic EL display device 1 may include a color filter, for example, to perform color tone expression of each of the subpixels SP.

Although each of the pixels PX is composed of subpixels SP of three colors in the first to third embodiments, no such limitation is intended. The subpixels SP constituting each pixel PX may have four or more colors. Although the subpixels SP of three colors constituting each pixel PX are provided in a stripe array, no such limitation is intended. The array of the plurality of subpixels PS may be another array such as PenTile arrangement.

Although the number of the plurality of TFTs 50 constituting the pixel circuit PC is three including the first TFT 50A, the second TFT 50B, and the third TFT 50C in the first to third embodiments, no such limitation is intended, and the number of the plurality of TFTs 50 constituting the pixel circuit PC may be 2 or smaller, or 4 or greater. In addition, each TFT 50 may be configured as a bottom-gate type.

Although the pixel electrodes 61 are set to an anode electrode and the common electrodes 63 is a cathode electrode in the first to third embodiments, no such limitation is intended. The organic EL display device 1 may be configured such that the pixel electrodes 61 function as a cathode electrode and the common electrode 63 functions as an anode electrode. In this case, the organic EL layer 62 has an inverted layered structure.

Although the organic EL layer 62 has a five-layer structure including the hole injection layer, the hole transport layer, the light-emitting layer, the electron transport layer, and the electron injection layer in the first to third embodiments, no such limitation is intended. The organic EL layer 62 may have a three-layer structure including a hole injection layer and hole transport layer, a light-emitting layer, and an electron transport layer and electron injection layer, and may employ any layered structure.

Although the substrate of the organic EL display device 1 is configured as a substrate layer in the first to third embodiments, no such limitation is intended. As the substrate, it is possible to use a substrate made of an arbitrary material as long as it has optical transparency, for example, a plastic substrate made of polyethylene terephthalate (PET) or a glass substrate.

Although the camera 3 is exemplified as an electronic component that can be combined with the organic EL display device 1 in the first to third embodiments, no such limitation is intended. The electronic component mentioned above may be another electronic component such as a fingerprint sensor, a face recognition sensor, or a luminance sensor as long as the electronic component is disposed at a position overlapping the second display region DA2 on the back face side of the organic EL display device 1, and configured to utilize the light transmitted through the display region DA.

Although the organic EL display device 1 has been exemplified as the display device according to the disclosure in the first to third embodiments, no such limitation is intended. The technique of the disclosure can be applied to a display device provided with a plurality of light-emitting elements to be driven by a current. Examples of the display device include a display device including a Quantum-dot light-emitting diode (QLED), which is a light-emitting element using a quantum dot-containing layer. In addition, the technique of the disclosure is also applicable to a liquid crystal display device and a plasma display device.

As described above, the preferred embodiments are described as examples of the technique of the disclosure. However, the technique of the disclosure is not limited to the embodiments and the modified examples, and is also applicable to an embodiment in which modification, replacement, addition, omission, and the like are suitably made. It is understood by those skilled in the art that various modified examples can be made to the above embodiment without departing from the spirit of the technology of the disclosure, and such modified examples also belong to the scope of the technology of the disclosure.

### INDUSTRIAL APPLICABILITY

As described above, the disclosure is useful for a display device.

1. A display device comprising:
a substrate;
a thin film transistor layer provided on the substrate; and
a light-emitting element layer provided on the thin film transistor layer,
wherein a plurality of thin film transistors are provided in the thin film transistor layer and a plurality of light-emitting elements are provided in the light-emitting element layer, the plurality of thin film transistors and the plurality of light-emitting elements being provided corresponding to each of a plurality of subpixels forming a display region,
an electronic component configured to use light is disposed on a back face side of the substrate at a position overlapping the display region in a plan view,
the display region includes a first display region and a second display region that is provided inside the first display region and transmits light to be used by the electronic component,
a connection line configured to electrically connect each of the plurality of thin film transistors and a corresponding one of the plurality of light-emitting elements is provided in the second display region,
the connection line includes a transparent wiring line layer having optical transparency,
a pixel electrode constituting each of the plurality of light-emitting elements in the second display region includes a first region provided overlapping the transparent wiring line layer and a second region formed on the same layer as the transparent wiring line layer,
the connection line includes a first connection line electrically connected to the pixel electrode and a second connection line electrically connecting the first connection line and each of the plurality of thin film transistors,
the first connection line is configured by the transparent wiring line layer, and
the second connection line is formed in a layer different from a layer in which the first connection line is formed and has optical transparency.

2.-3. (canceled)

4. The display device according to claim 1,
wherein the light-emitting element layer includes an edge cover provided to cover an outer edge of the pixel electrode, and
a peripheral edge of an opening of the edge cover through which the pixel electrode is partially exposed is surrounded by the outer edge of the pixel electrode in a plan view.

5. The display device according to claim 1,
wherein the transparent wiring line layer is formed of a transparent conductive material which is crystallized, and
the transparent conductive material has a property of being less corroded by a predetermined etching solution after being crystallized while being corroded by the predetermined etching solution before being crystallized.

6. The display device according to claim 5,
wherein the transparent conductive material is indium tin oxide.

7. The display device according to claim
wherein the pixel electrode includes a conductive layered body in which a first transparent electrode layer having optical transparency, a reflective electrode layer having light reflectivity, and a second transparent electrode layer having optical transparency are sequentially layered, and
all the first transparent electrode layer, the reflective electrode layer, and the second transparent electrode layer are formed of a conductive material having a property of being etched by the etching solution.

8. (canceled)

9. The display device according to claim 1,
wherein the second display region includes a light-emitting element region in which the plurality of light-emitting elements are disposed, and
a pixel circuit configured to control light emission of the light-emitting element disposed in the light-emitting element region is provided around the light-emitting element region, the pixel circuit including the plurality of thin film transistors.

10. The display device according to claim 9,
wherein a plurality of sets of the light-emitting elements are disposed in the light-emitting element region, each set being formed by two or more of the light-emitting elements, and
the pixel circuit is provided for each set of the light-emitting elements and controls light emission of the two or more light-emitting elements forming the set together.

11.-12. (canceled)

13. A display device comprising:
a substrate;
a thin film transistor layer provided on the substrate; and
a light-emitting element layer provided on the thin film transistor layer,
wherein a plurality of thin film transistors are provided in the thin film transistor layer and a plurality of light-emitting elements are provided in the light-emitting element layer, the plurality of thin film transistors and the plurality of light-emitting elements being provided corresponding to each of a plurality of subpixels forming a display region,
an electronic component configured to use light is disposed on a back face side of the substrate at a position overlapping the display region in a plan view,
the display region includes a first display region and a second display region that is provided inside the first display region and transmits light to be used by the electronic component,
a connection line configured to electrically connect each of the plurality of thin film transistors and a corresponding one of the plurality of light-emitting elements is provided in the second display region,
the connection line includes a transparent wiring line layer having optical transparency,
a pixel electrode constituting each of the plurality of light-emitting elements in the second display region includes a first region provided overlapping the transparent wiring line layer and a second region formed on the same layer as the transparent wiring line layer,
the second display region includes a light-emitting element region in which the plurality of light-emitting elements are disposed, and
a pixel circuit configured to control light emission of the light-emitting element disposed in the light-emitting element region is provided around the light-emitting element region, the pixel circuit including the plurality of thin film transistors.

14. The display device according to claim 13,
wherein the light-emitting element layer includes an edge cover provided to cover an outer edge of the pixel electrode, and
a peripheral edge of an opening of the edge cover through which the pixel electrode is partially exposed is surrounded by the outer edge of the pixel electrode in a plan view.

15. The display device according to claim 13,
wherein the transparent wiring line layer is formed of a transparent conductive material which is crystallized, and
the transparent conductive material has a property of being less corroded by a predetermined etching solution after being crystallized while being corroded by the predetermined etching solution before being crystallized.

16. The display device according to claim 13,
wherein a plurality of sets of the light-emitting elements are disposed in the light-emitting element region, each set being formed by two or more of the light-emitting elements, and
the pixel circuit is provided for each set of the light-emitting elements and controls light emission of the two or more light-emitting elements forming the set together.

17. A display device comprising:
a substrate;
a thin film transistor layer provided on the substrate; and
a light-emitting element layer provided on the thin film transistor layer,
wherein a plurality of thin film transistors are provided in the thin film transistor layer and a plurality of light-emitting elements are provided in the light-emitting element layer, each of the plurality of thin film transistors and the plurality of light-emitting elements being provided corresponding to each of a plurality of subpixels forming a display region,
an electronic component configured to use light is disposed on a back face side of the substrate at a position overlapping the display region in a plan view,
the display region includes a first display region and a second display region that is provided inside the first display region and transmits light to be used by the electronic component,
a connection line configured to electrically connect each of the plurality of thin film transistors and a corresponding one of the plurality of light-emitting elements is provided in the second display region,
the connection line includes a transparent wiring line layer having optical transparency, and
a pixel electrode constituting each of the plurality of light-emitting elements in the first display region includes a first region provided overlapping a transparent conductive layer formed of the same material and in the same layer as the transparent wiring line layer and a second region formed on the same layer as the transparent conductive layer.

18. The display device according to claim 17,
wherein the pixel electrode in the first display region covers an entire circumference of an outer edge of the transparent conductive layer.

19. The display device according to claim 17,
wherein the light-emitting element layer includes an edge cover provided to cover an outer edge of the pixel electrode, and
a peripheral edge of an opening of the edge cover through which the pixel electrode is partially exposed is surrounded by the outer edge of the pixel electrode in a plan view.

20. The display device according to claim 17,
wherein the transparent wiring line layer is formed of a transparent conductive material which is crystallized, and
the transparent conductive material has a property of being less corroded by a predetermined etching solution after being crystallized while being corroded by the predetermined etching solution before being crystallized.

21. The display device according to claim 20,
wherein the transparent conductive material is indium tin oxide.

22. The display device according to claim 20,
wherein the pixel electrode includes a conductive layered body in which a first transparent electrode layer having optical transparency, a reflective electrode layer having light reflectivity, and a second transparent electrode layer having optical transparency are sequentially layered, and
all the first transparent electrode layer, the reflective electrode layer, and the second transparent electrode layer are formed of a conductive material having a property of being etched by the etching solution.

23. The display device according to claim 17,
wherein the connection line includes a first connection line electrically connected to the pixel electrode and a second connection line electrically connecting the first connection line and each of the plurality of thin film transistors,
the first connection line is configured by the transparent wiring line layer, and
the second connection line is formed in a layer different from a layer in which the first connection line is formed and has optical transparency.

24. The display device according to claim 17,
wherein the second display region includes a light-emitting element region in which the plurality of light-emitting elements are disposed, and
a pixel circuit configured to control light emission of the light-emitting element disposed in the light-emitting element region is provided around the light-emitting element region, the pixel circuit including the plurality of thin film transistors.

25. The display device according to claim 24,
wherein a plurality of sets of the light-emitting elements are disposed in the light-emitting element region, each set being formed by two or more of the light-emitting elements, and
the pixel circuit is provided for each set of the light-emitting elements and controls light emission of the two or more light-emitting elements forming the set together.
